(19) United States
(12) Patent Application Publication
(10) Pub. No.: US 2025/0365875 A1
(43) Pub. Date: Nov. 27, 2025

(54) ELECTRONIC DEVICE COMPRISING ACTUATOR AND RACK GEAR PARALLEL TO EACH OTHER

(71) Applicant: Samsung Electronics Co., Ltd., Suwon-si (KR)

(72) Inventors: Changhee YOO, Suwon-si (KR); Yonghwa KIM, Suwon-si (KR); Hyunggwang KANG, Suwon-si (KR); Yongyeon KIM, Suwon-si (KR); Hoyoung JEONG, Suwon-si (KR); Hyoungtak CHO, Suwon-si (KR); Yangwook KIM, Suwon-si (KR); Soyoung LEE, Suwon-si (KR)

(21) Appl. No.: 19/057,454

(22) Filed: Feb. 19, 2025

Related U.S. Application Data
(63) Continuation of application No. PCT/KR2025/002075, filed on Feb. 12, 2025.

(30) Foreign Application Priority Data
May 23, 2024 (KR) 10-2024-0067299
Jun. 20, 2024 (KR) 10-2024-0080672

(51) Int. Cl. H05K 5/02

(52) U.S. Cl. CPC H05K 5/0217

(57) ABSTRACT

An electronic device includes a housing including a first housing part and a second housing part movably coupled to the first housing part, a driving mechanism, a battery, and a printed circuit board. The driving mechanism includes an actuator disposed to have a rotation axis parallel to a direction of the movement of the second housing part, and a rack gear extending parallel to the direction. The printed circuit board includes a first region including a plurality of layers and a single layer, and includes a second region overlapping the battery.

### CROSS-REFERENCE TO RELATED APPLICATION(S)

This application is a continuation application, claiming priority under 35 U.S.C. § 365(c), of an International application No. PCT/KR2025/002075, filed on Feb. 12, 2025, which is based on and claims the benefit of a Korean patent application number 10-2024-0067299, filed on May 23, 2024, in the Korean Intellectual Property Office, and of a Korean patent application number 10-2024-0080672, filed on Jun. 20, 2024, in the Korean Intellectual Property Office, the disclosure of each of which is incorporated by reference herein in its entirety.

### TECHNICAL FIELD

The disclosure relates to an electronic device including an actuator and a rack gear parallel to each other.

### BACKGROUND ART

An electronic device may include a plurality of housing parts that are movably coupled. For example, the electronic device may include a first housing part and a second housing part movably coupled to the first housing part. The electronic device may include a driving mechanism that causes a movement of the first housing part and/or the second housing part. The driving mechanism may operate based on power from a battery. A charging capacity of the battery may be proportional to a size of the battery.

The above information is presented as background information only to assist with an understanding of the disclosure. No determination has been made, and no assertion is made, as to whether any of the above might be applicable as prior art with regard to the disclosure.

### DISCLOSURE

### Technical Solution

Aspects of the disclosure are to address at least the above-mentioned problems and/or disadvantages and to provide at least the advantages described below. Accordingly, an aspect of the disclosure is to provide an electronic device including an actuator and a rack gear parallel to each other.

Additional aspects will be set forth in part in the description which follows and, in part, will be apparent from the description, or may be learned by practice of the presented embodiments.

An electronic device is provided. The electronic device may comprise a housing including a first housing part and a second housing part, movably coupled to each other. The electronic device may comprise a driving mechanism configured to cause a movement of the first housing part or a movement the second housing part. The electronic device may comprise a printed board assembly (PBA) disposed in the first housing part, and including a first region which is a laminating region of printed circuit boards, and a second region which is a non-laminating region. The electronic device may comprise a battery disposed in the first housing part. The driving mechanism may include an actuator disposed to have a rotation axis parallel to a direction of the movement of the first housing part or the second housing part and a rack gear disposed parallel to the rotation axis. The battery may be positioned over the second region among the first region and the second region.

An electronic device is provided. The electronic device may comprise a housing including a first housing part and a second housing part movably coupled to the first housing part. The electronic device may comprise a driving mechanism configured to cause a movement of the second housing part relative to the first housing part. The driving mechanism may include an actuator disposed in the first housing part to have a rotation axis parallel to a direction of the movement of the second housing part. The driving mechanism may include a rack gear coupled to the second housing part and extended parallel to the direction. The driving mechanism may include a pinion gear, operatively coupled to the actuator, configured to rotate based on an operation of the actuator, and engaged with the rack gear. The driving mechanism may include one or more gear connected to each of the actuator and the pinion gear to transmit driving force from the actuator to the pinion gear. The electronic device may comprise a bracket including a guide rail to guide translation of the rack gear. The guide rail may comprise a first side wall contacted with a portion of a side of the rack gear, and a second side wall contacted with a portion of another side of the rack gear opposite to the side of rack gear, and including an opening region to reduce a gap between the actuator and the rack gear. The one or more gears may be closer to the second side wall among the first side wall and the second side wall.

Other aspects, advantages, and salient features of the disclosure will become apparent to those skilled in the art from the following detailed description, which, taken in conjunction with the annexed drawings, discloses various embodiments of the disclosure.

### DESCRIPTION OF THE DRAWINGS

FIG. 1 is a block diagram of an electronic device in a network environment according to an embodiment.

FIG. 2A is a front view of an electronic device according to an embodiment in a first state.

FIG. 2B is a rear view of an electronic device according to an embodiment in a first state.

FIG. 2C is a plan view of an electronic device according to an embodiment in a second state.

FIG. 2D is a rear view of an electronic device according to an embodiment in a second state.

FIG. 3A illustrates an interior of an electronic device according to an embodiment a first state.

FIG. 3B illustrates an interior of an electronic device according to an embodiment in a second state.

FIG. 4A is a cross-sectional view of an electronic device according to an embodiment cut along line A-A′ of FIG. 3A.

FIG. 4B is a cross-sectional view of an electronic device according to an embodiment cut along line B-B′ of FIG. 3B.

FIG. 4C illustrates a printed board assembly, a battery, and a flexible display of FIG. 4A.

FIG. 4D illustrates a printed board assembly, a battery, and a flexible display of FIG. 4B.

FIG. 5A illustrates a printed board assembly and a battery of an electronic device according to an embodiment.

FIG. 5B illustrates a flexible display and a printed board assembly of an electronic device according to an embodiment in a first state.

FIGS. 6A and 6B illustrate a driving mechanism and a bracket of an electronic device according to an embodiment.

FIG. 6C illustrates a bracket according to an embodiment.

FIG. 7A is a side view of a driving mechanism illustrated in FIG. 6A.

FIG. 7B illustrates a driving mechanism in which teeth of a rack gear are disposed to face a rear of an electronic device.

FIG. 7C is a side view of a driving mechanism illustrated in FIG. 7B.

FIG. 8 illustrates one or more gears according to an embodiment.

FIG. 9A illustrates one or more gears according to an embodiment.

FIG. 9B illustrates a portion of a driving mechanism including one or more gears illustrated in FIG. 9A.

FIG. 10A illustrates an interior of an electronic device according to an embodiment in a first state.

FIG. 10B illustrates an interior of an electronic device according to an embodiment in a second state.

### MODE FOR INVENTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include computer-executable instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g., a central processing unit (CPU)), a communication processor (CP, e.g., a modem), a graphical processing unit (GPU), a neural processing unit (NPU) (e.g., an artificial intelligence (AI) chip), a wireless-fidelity (Wi-Fi) chip, a Bluetooth™ chip, a global positioning system (GPS) chip, a near field communication (NFC) chip, connectivity chips, a sensor controller, a touch controller, a finger-print sensor controller, a display drive integrated circuit (IC), an audio CODEC chip, a universal serial bus (USB) controller, a camera controller, an image processing IC, a microprocessor unit (MPU), a system on chip (SoC), an IC, or the like.

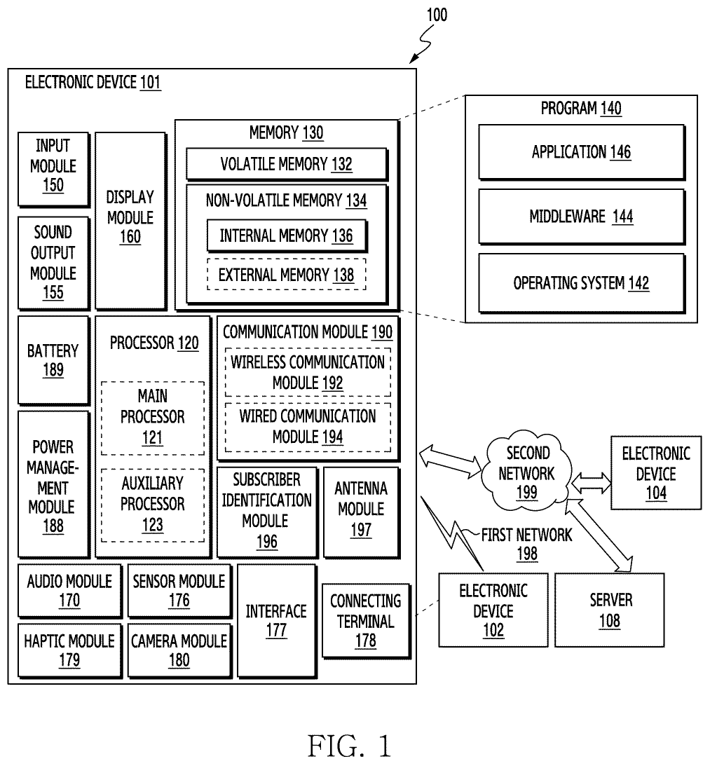

FIG. 1 is a block diagram of an electronic device in a network environment according to an embodiment.

Referring to FIG. 1, an electronic device 101 in a network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module(SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., a sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment of the disclosure, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™ wireless-fidelity (Wi-Fi) direct, or infrared data association (IrDA)) or the second network 199 (e.g., a long-range communication network, such as a legacy cellular network, a fifth generation (5G) network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a fourth generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the millimeter wave (mmWave) band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, an RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102 or 104, or the server 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., a smart home, a smart city, a smart car, or healthcare) based on 5G communication technology or IoT-related technology.

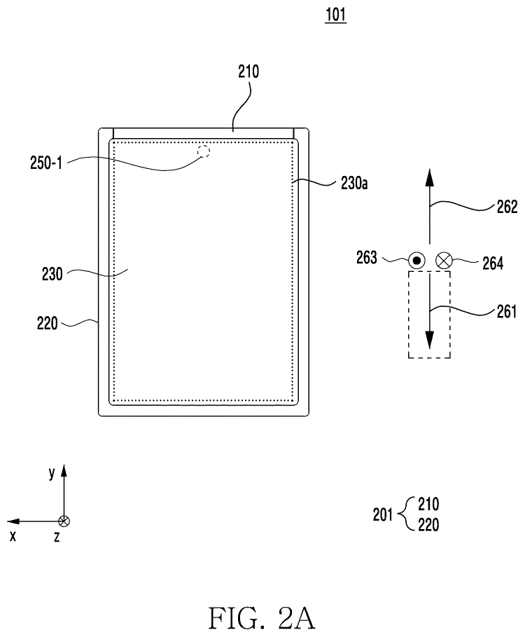

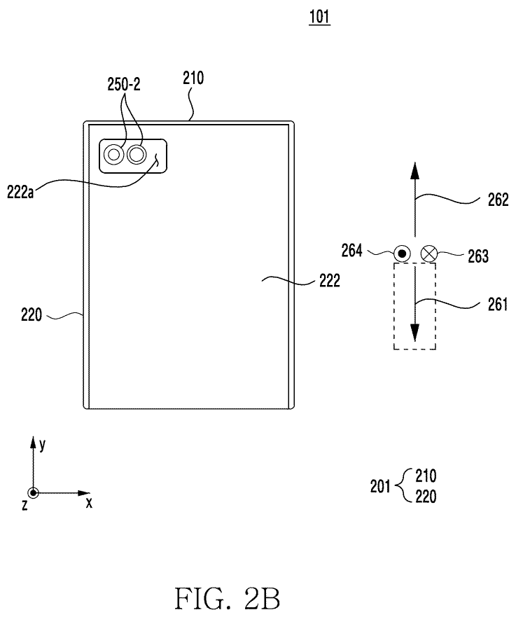

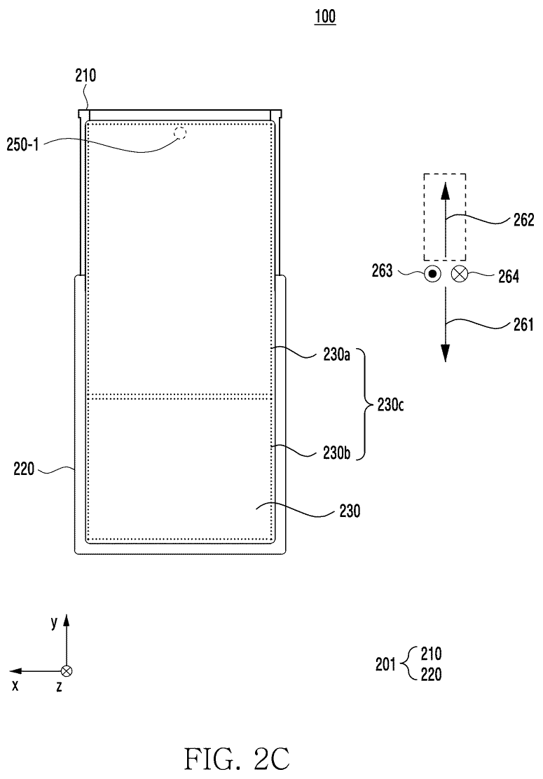

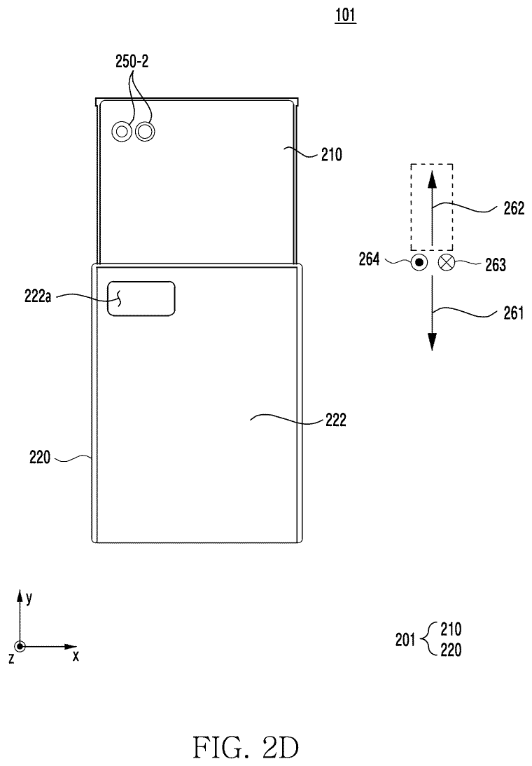

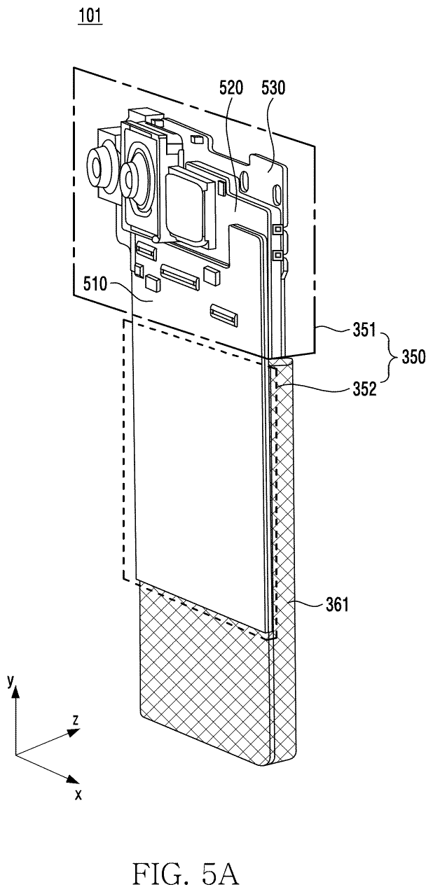

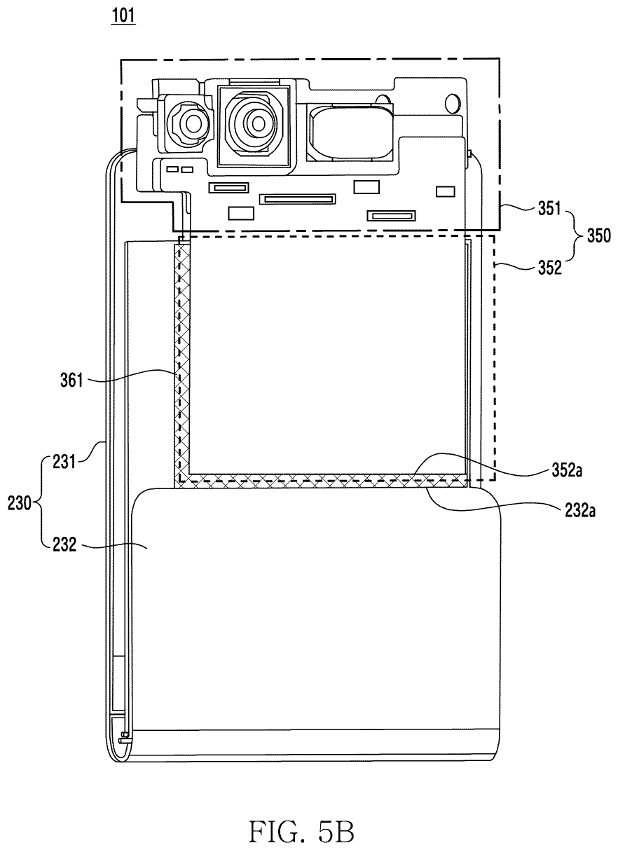

For example, a display of the display module 160 may be flexible. For example, the display may include a display area exposed outside a housing (e.g., a housing 201 of FIG. 5A) of the electronic device 101 that provides at least a portion of an outer surface of the electronic device 101. For example, since the display has flexibility, at least a portion of the display may be rollable into the housing or slidable into the housing. For example, a size of the display area may be changed depending to a size of the at least a portion of the display rolled into the housing or slid into the housing. For example, the electronic device 101 including the display may be in a plurality of states including a first state providing the display area having a first size and a second state providing the display area having a second size different from the first size. For example, the first state may be exemplified through a description of FIGS. 2A and 2B.

FIG. 2A is a front view of an electronic device according to an embodiment in a first state.

Referring to FIG. 2A, an electronic device 101 may include a housing 201 and a flexible display 230 (e.g., the display module 160 of FIG. 1). For example, the housing 201 may include a first housing part 210 and a second housing part 220 that is movably coupled to the first housing part 210. For example, the second housing part 220 may be movable relative to the first housing part 210 in a first direction 261 parallel to a y-axis, or a second direction 262 parallel to the y-axis and opposite to the first direction 261.

Although in the disclosure, it is described that the second housing part 220 is moved relative to the first housing part 210, embodiments of the disclosure are not limited thereto. For example, the housing 201 may have a structure in which an overall size of the housing 201 may change according to a change in a relative positional relationship between the first housing part 210 and the second housing part 220. The relative positional relationship between the first housing part 210 and the second housing part 220 may be changed by an operation of a driving mechanism to be described later. For example, the first housing part 210 may be movable relative to the second housing part 220 by the driving mechanism. For example, both the first housing part 210 and the second housing part 220 may be movable by the driving mechanism.

According to an embodiment, the electronic device 101 may be in the first state. In the first state, the second housing part 220 may be movable relative to the first housing part 210 in the first direction 261 among the first direction 261 and the second direction 262. For example, in the first state, the second housing part 220 may not be substantially movable in the second direction 262 relative to the first housing part 210. The first direction 261 may be referred to as a direction in which the second housing part 220 moves away from the first housing part 210. The first direction 261 may be referred to as a −y direction of FIG. 2A. The second direction 262 may be referred to as a direction in which the second housing part 220 approaches the first housing part 210. The second direction 262 may be referred to as a +y direction of FIG. 2A.

For example, in the first state, the flexible display 230 may provide a display region having the smallest size. For example, in the first state, the display region may correspond to a first display region 230a. Although not illustrated in FIG. 2A, in the first state, a second display region (e.g., a second display region 230b of FIG. 2C) of the flexible display 230 different from the first display region 230a, which is the display region, may be included in the first housing part 210. In the first state, the second display region 230b may be covered by the first housing part 210. In the first state, the second display region 230b may be rolled into the first housing part 210.

The first state may be referred to as a slide-in state or a closed state from a perspective that at least a portion of the second housing part 220 is located in the first housing part 210, and from a perspective that the region where the first housing part 210 and the second housing part 220 are arranged to partially overlap each other is the largest. For example, the first state may be referred to as a reduced state in terms of providing the display region having the smallest size. However, it is not limited thereto.

For example, the first housing part 210 may include a first image sensor 250-1 in a camera module (e.g., the camera module 180 of FIG. 1), exposed through a portion of the first display region 230a and facing in a third direction 263 parallel to a z-axis. Although not illustrated in FIG. 2A, the first housing part 210 may include one or more second image sensors in a camera module 180, exposed through a portion of the first housing part 210 and facing in a fourth direction 264 parallel to the z-axis and opposite to the third direction 263. For example, the one or more second image sensors may be exemplified through a description of FIG. 2B.

FIG. 2B is a rear view of an electronic device according to an embodiment in a first state.

Referring to FIG. 2B, in the first state, the one or more second image sensors 250-2 disposed in the first housing part 210, may be positioned within a structure disposed in the second housing part 220 for the one or more second image sensors 250-2. For example, light from the outside of the electronic device 101 may be received by the one or more second image sensors 250-2 through the structure in the first state. Since the one or more second image sensors 250-2 are positioned within the structure in the first state, the one or more second image sensors 250-2 may be exposed through the structure in the first state. For example, the structure may be variously implemented. For example, the structure may be an opening or a notch. For example, the structure may be an opening 222a in a rear plate 222 of the second housing part 220 surrounding at least a portion of the first housing part 210. However, it is not limited thereto.

For example, the first state may be changed to a second state.

For example, the first state (or the second state) may be changed to the second state (or the first state) through intermediate states between the first state and the second state.

For example, the first state (or the second state) may be changed to the second state (or the first state) based on a user input. For example, the first state (or the second state) may be changed to the second state (or the first state), in response to the user input on a physical button exposed through a portion of the first housing part 210 or a portion of the second housing part 220. For example, the first state (or the second state) may be changed to the second state (or the first state), in response to a touch input on an executable object displayed in the display region. For example, the first state (or the second state) may be changed to the second state (or the first state), in response to a touch input that has a contact point and a pressing force greater than or equal to a reference force on the display region. For example, the first state (or the second state) may be changed to the second state (or the first state), in response to a voice input received through a microphone of the electronic device 101. For example, the first state (or the second state) may be changed to the second state (or the first state), in response to an external force applied to the first housing part 210 and/or the second housing part 220 to move the second housing part 220 relative to the first housing part 210. For example, the first state (or the second state) may change to the second state (or the first state), in response to a user input identified on an external electronic device (e.g., earbuds or a smart watch) connected to the electronic device 101. However, it is not limited thereto.

The second state may be exemplified through a description of FIGS. 2C and 2D.

FIG. 2C is a plan view of an electronic device according to an embodiment in a second state.

Referring to FIG. 2C, the electronic device 101 may be in the second state. For example, in the second state, the second housing part 220 may be movable relative to the first housing part 210 in the second direction 262 among the first direction 261 and the second direction 262. For example, in the second state, the second housing part 220 may not be substantially movable in the first direction 261 relative to the first housing part 210.

For example, in the second state, the flexible display 230 may provide a display region having the largest size. For example, in the second state, the display region may correspond to a region 230c including the first display region 230a and the second display region 230b. The second display region 230b, which was disposed inside the first housing part 210 or outside at least a portion of the first housing part 210 in the first state may be exposed in the second state.

For example, the second state may be referred to as a slide-out state or an open state in terms of increasing a size of a display region of the flexible display 230 exposed to the outside of the first housing part 210 and the second housing part 220 due to a movement of the first housing part 210 or the second housing part 220. For example, the second state may be referred to as an extended state in terms of providing the display region having the largest size. However, it is not limited thereto.

For example, when a state of the electronic device 101 changes from the first state to the second state, the first image sensor 250-1 facing the third direction 263 may be moved together with the first display region 230a along the movement of the second housing part 220 in the first direction 261 or the movement of the first housing part 210 in the second direction 262. Although not illustrated in FIG. 2C, the one or more second image sensors (e.g., the one or more second image sensors 250-2 of FIG. 2D) facing the fourth direction 264 may be moved along the movement of the second housing part 220 in the first direction 261 or the movement of the first housing part 210 in the second direction 262, when the state of the electronic device 101 changes from the first state to the second state. For example, a relative positional relationship between the one or more second image sensors 250-2 and the structure exemplified through the description of FIG. 2B may change along the movement of the one or more second image sensors 250-2. For example, the change in the relative positional relationship may be exemplified through FIG. 2D.

FIG. 2D is a rear view of an electronic device according to an embodiment in a second state.

Referring to FIG. 2D, in the second state, the one or more second image sensors 250-2 may be positioned outside the structure. For example, the structure may include an opening 212a. For example, in the second state, the one or more second image sensors 250-2 may be positioned outside the opening 222a in a first plate 212. As described with reference to FIG. 2B, the one or more second image sensors 250-2 may be exposed through the opening 212a in the first state. Since the one or more second image sensors 250-2 are positioned outside the first housing part 210 in the second state, the one or more second image sensors 250-2 may be exposed in the second state. Since the one or more second image sensors 250-2 are positioned outside the structure in the second state, the relative positional relationship in the second state may be different from the relative positional relationship in the first state.

For example, in case that the electronic device 101 does not include the structure, such as the opening 212a, the one or more second image sensors 250-2 may be exposed in the second state among the first state and the second state.

Although not illustrated in FIGS. 2A, 2B, 2C, and 2D, the electronic device 101 may be in an intermediate state between the first state and the second state. For example, a size of a display region in the intermediate state may be larger than a size of the display region in the first state and may be smaller than a size of the display region in the second state. For example, the display region in the intermediate state may correspond to a region including a portion of the first display region 230a and the second display region 230b. For example, in the intermediate state, a portion of the second display region 230b may be exposed, and another portion (or a remaining portion) of the second display region 230b may be covered by the first housing part 210 or rolled into the first housing part 210. However, it is not limited thereto.

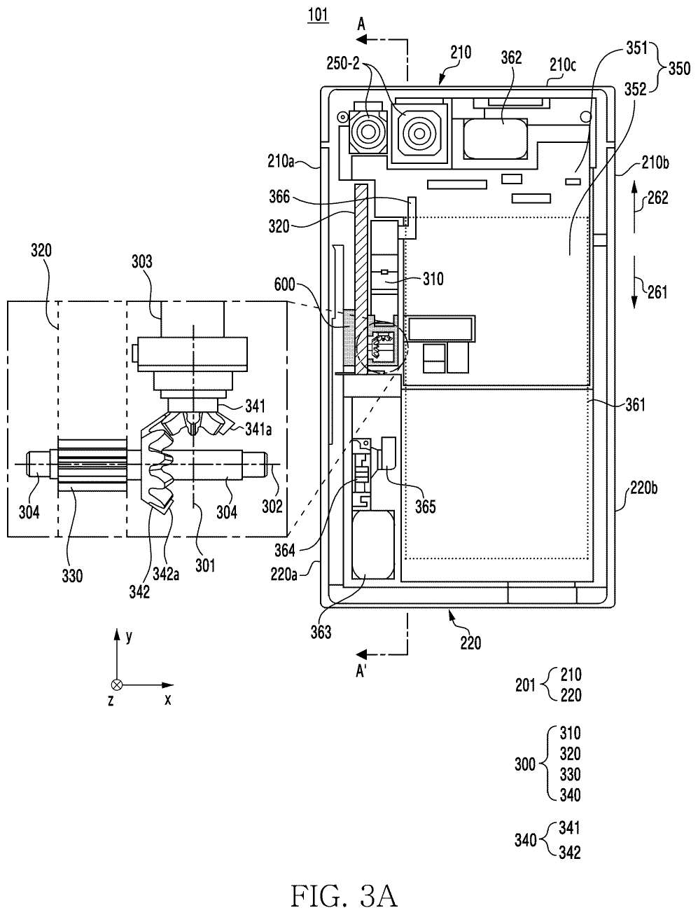

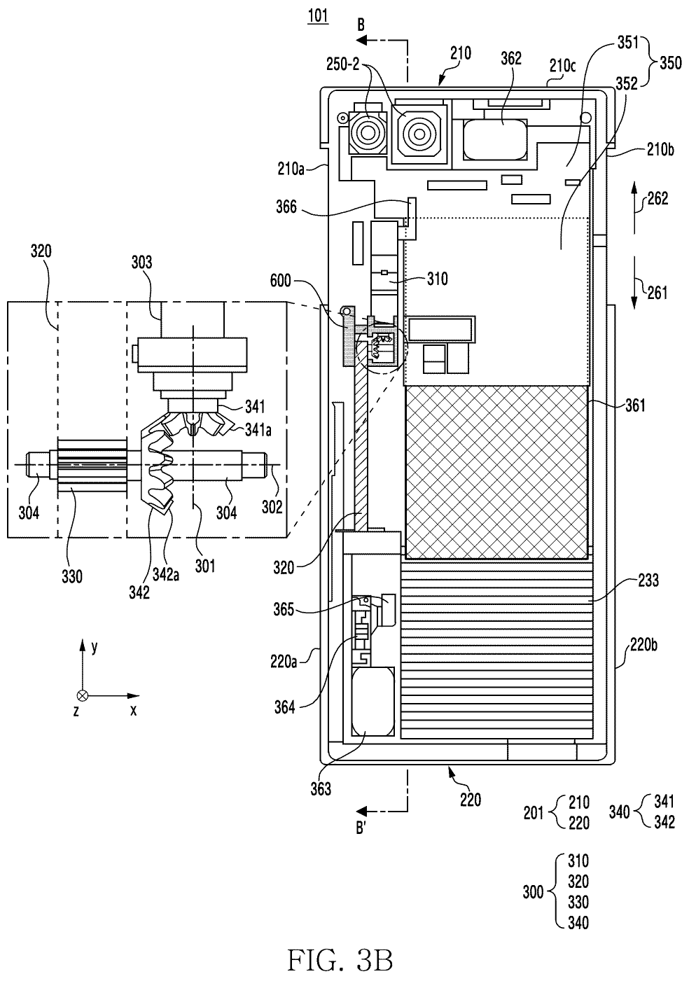

According to an embodiment, the electronic device 101 may include structures for moving the second housing (e.g., the second housing part 220 of FIG. 2A) of the electronic device 101 relative to the first housing (e.g., the first housing part 210 of FIG. 2A) of the electronic device 101. For example, the structures may be exemplified through a description of FIGS. 3A and 3B.

In the disclosure, terms, such as “over”, “below”, “a side”, and “another side” should be understood as terms that indicate a relative positional relationship, not terms that indicate an absolute positional relationship, and as terms that are specified for convenience of explanation. For example, when an electronic device illustrated in a drawing is flipped, ‘up’ and ‘down’ may be switched.

FIG. 3A illustrates an interior of an electronic device according to an embodiment a first state. FIG. 3B illustrates an interior of an electronic device according to an embodiment in a second state.

Referring to FIG. 3A, an electronic device 101 may include a driving mechanism 300 configured to cause a movement of a second housing part 220 relative to a first housing part 210. The driving mechanism 300 may include an actuator 310 and a rack gear 320.

According to an embodiment, the actuator 310 may operate based on power provided from a battery 361. The power may be provided to the actuator 310 in response to a user input. The actuator 310 may be disposed to have a first rotation axis 301 parallel to a direction (e.g., a direction parallel to a y-axis) of the movement of the second housing part 220. The first rotation axis 301 may be parallel to a first direction 261 and/or a second direction 262. When the power is provided from the battery 361 to the actuator 310, a first shaft 303 connected to the actuator 310 may be rotated with respect to the first rotation axis 301.

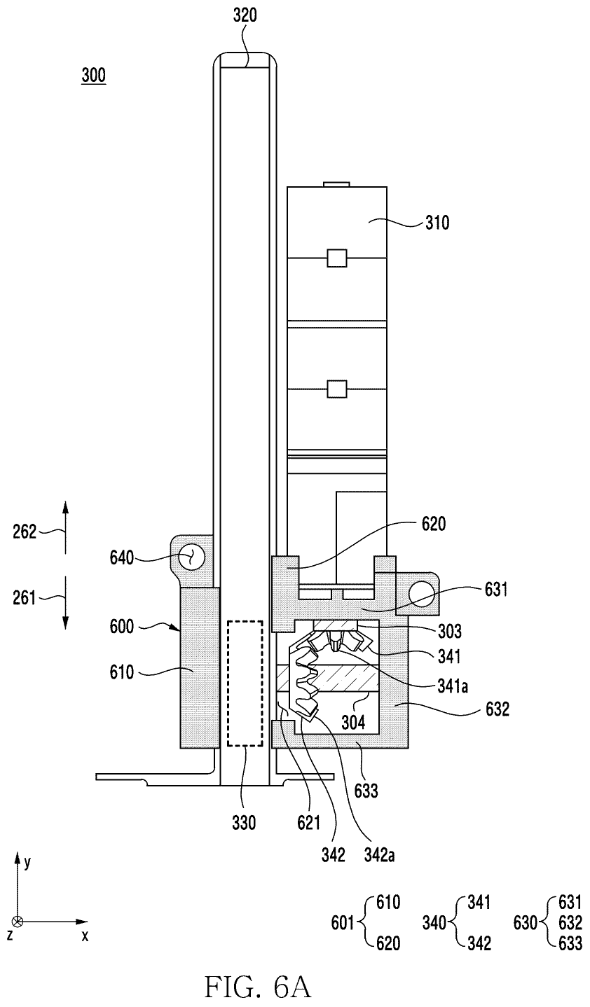

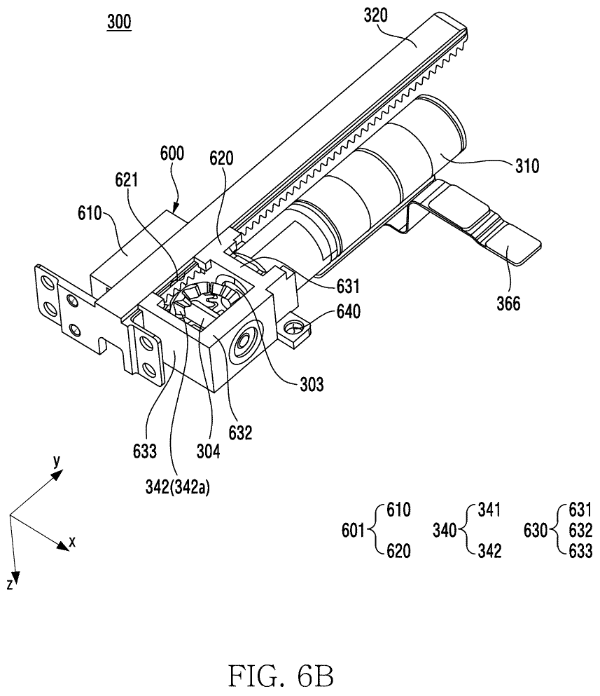

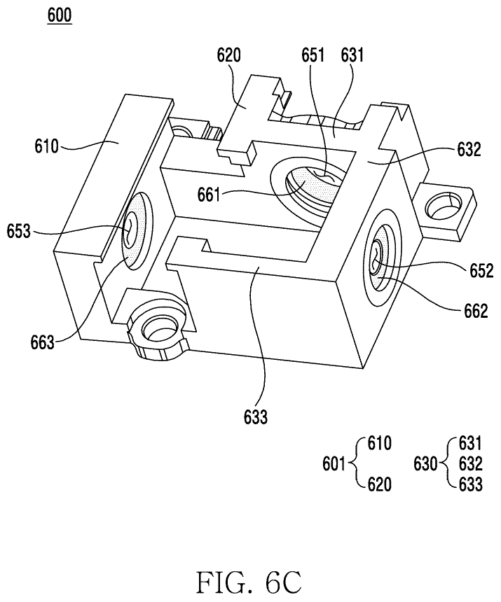

According to an embodiment, the rack gear 320 may be coupled to the second housing part 220. The rack gear 320 may extend parallel to the direction of the movement of the second housing part 220. The rack gear 320 may be parallel to the first rotation axis 301 of the actuator 310. For example, the rack gear 320 may extend parallel to the first direction 261 and/or the second direction 262. The rack gear 320 may translate along the first direction 261 and/or the second direction 262. The electronic device 101 may include a bracket 600 to guide the translation of the rack gear 320. The bracket 600 will be described later with reference to FIG. 6A.

According to an embodiment, the driving mechanism 300 may include a pinion gear 330 and one or more gears 340.

According to an embodiment, the pinion gear 330 may be operatively coupled to the actuator 310. The pinion gear 330 being operatively coupled to the actuator 310 may be referred to as the pinion gear 330 not being directly coupled to the actuator 310, but instead of the pinion gear 330 being connected to the actuator 310 through the one or more gears 340. The pinion gear 330 may be rotated based on an operation of the actuator 310.

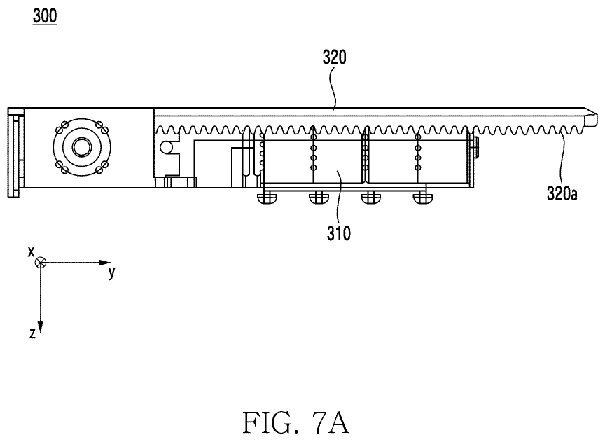

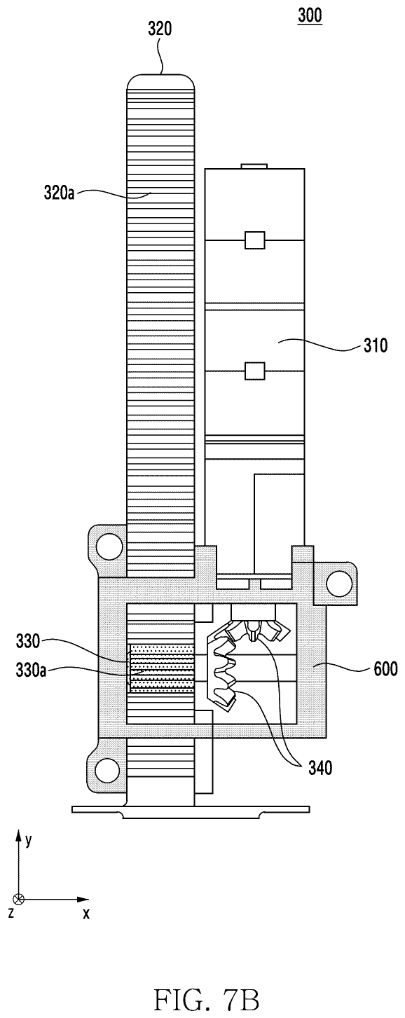

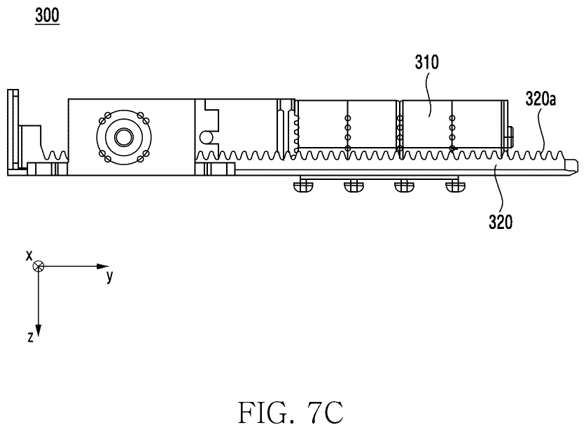

According to an embodiment, the rack gear 320 may be arranged with the pinion gear 330. For example, teeth (e.g., teeth 320a of FIG. 7A) of the rack gear 320 may be engaged with teeth 330a of the pinion gear 330. When the pinion gear 330 is rotated, the rack gear 320 may be moved based on rotation of the pinion gear 330.

According to an embodiment, the one or more gears 340 may be connected to each of the actuator 310 and the pinion gear 330, in order to transmit driving force of the actuator 310 to the pinion gear 330. For example, the one or more gears 340 may include a first gear 341 connected to the actuator 310 and a second gear 342 connected to the pinion gear 330. The first gear 341 may include first teeth 341a, and may be connected to the first shaft 303 connected to the actuator 310. The second gear 342 may include second teeth 342a engaged with the first teeth 341a, and may be connected to a second shaft 304 connected to the pinion gear 330. The first gear 341 may be configured to rotate based on the operation of the actuator 310. The second gear 342 may be configured to cause the rotation of the pinion gear 330, by being rotated based on rotation of the first gear 341.

According to an embodiment, the one or more gears 340 may include a bevel gear and/or a helical gear to transmit driving force between two intersecting axes. For example, the first shaft 303 connected to the actuator 310 may be parallel to the first direction 261 and/or the second direction 262. The second shaft 304 connected to the pinion gear 330 may be disposed perpendicular to the first direction 261 and/or the second direction 262. When the actuator 310 operates, the first gear 341 may be rotated with respect to the first rotation axis 301 of the actuator 310. The second gear 342 engaged with the first gear 341 may be rotated with respect to a second rotation axis 302 perpendicular to the first rotation axis 301 of the actuator 310. When the second gear 342 rotates with respect to the second rotation axis 302, the pinion gear 330 may be rotated with respect to the second rotation axis 302. As the pinion gear 330 is rotated, the rack gear 320 engaged with the pinion gear 330 may be moved in the first direction 261 or the second direction 262.

According to an embodiment, the rack gear 320 extending parallel to the first direction 261 and/or the second direction 262 may be moved in the first direction 261 or the second direction 262 based on the rotation of the pinion gear 330. The rack gear 320 may be coupled to the second housing part 220. The second housing part 220 may be moved in the first direction 261 or the second direction 262 by the rack gear 320 that moves based on the rotation of the pinion gear 330.

For example, in the first state of the electronic device 101 illustrated in FIG. 3A, the actuator 310 may be operated based on at least a portion of a user input. The first gear 341 may be rotated in a first rotation direction with respect to the first rotation axis 301, based on at least a portion of the operation of the actuator 310. The second gear 342 and the pinion gear 330 may be rotated based on the rotation of the first gear 341 in the first rotation direction (e.g., clockwise or counterclockwise). As the pinion gear 330 is rotated, the rack gear 320 may be moved in the first direction 261 (e.g., a −y direction). As the rack gear 320 moves in the first direction 261, the second housing part 220 coupled to the rack gear 320 may be moved in the first direction 261, and a state of the electronic device 101 may be converted from the first state to the second state illustrated in FIG. 3B, through a plurality of intermediate states.

For example, in the second state of the electronic device 101 illustrated in FIG. 3B, the actuator 310 may be operated based on at least a portion of the user input. The first gear 341 may be rotated in a second rotation direction opposite to the first rotation direction with respect to the first rotation axis 301 based on at least a portion of the operation of the actuator 310. The second gear 342 and the pinion gear 330 may be rotated, based on the rotation of the first gear 341 in the second rotation direction (e.g., the counterclockwise or the clockwise). As the pinion gear 330 is rotated, the rack gear 320 may be moved in the second direction 262 (e.g., a +y direction). As the rack gear 320 moves in the second direction 262, the second housing part 220 coupled to the rack gear 320 may be moved in the second direction 262, and the state of the electronic device 101 may be converted from the second state to the first state illustrated in FIG. 3A, through the plurality of intermediate states.

In the description described above, it is described that the second housing part 220 is moved by the driving mechanism 300, but embodiments of the disclosure are not limited thereto. For example, unlike the description described above, the rack gear 320 may be coupled to the first housing part 210. In this case, when the actuator 310 is rotated, the first housing part 210 connected to the rack gear 320 may be moved in the first direction 261 or the second direction 262.

According to an embodiment, the electronic device 101 may further include a printed board assembly 350 and the battery 361.

According to an embodiment, the printed board assembly 350 may be disposed in the first housing part 210. The printed board assembly 350 may be configured to provide an electrical connection between electronic components of the electronic device 101. For example, a processor (e.g., the processor 120 of FIG. 1) may be electrically connected to the electronic components (e.g., one or more speakers (e.g., a first speaker 362 and a second speaker 363), and one or more image sensors 250-2) of the electronic device 101 through the printed board assembly 350. For example, the printed board assembly 350 and the actuator 310 may be electrically connected through a connection member 366 (e.g., a flexible printed board assembly). The printed board assembly 350 may be adjacent to a fifth edge portion 210c of the first housing part 210. The fifth edge portion 210c may be perpendicular to a first edge portion 210a of the first housing part 210 and may be spaced apart from the second housing part 220.

According to an embodiment, the printed board assembly 350 may include a first region 351 and a second region 352. The first region 351 may be a laminating region of a plurality of printed circuit boards. The first region 351 may include a plurality of layers. For example, the first region 351 may include a plurality of conductive layers and a plurality of non-conductive layers alternately laminated with the plurality of conductive layers. The first region 351 may provide the electrical connection between the electronic components using wires and conductive vias, formed on the conductive layer. For example, the processor may be disposed on the first region 351.

For example, the second region 352 may be a non-laminating region. The second region 352 may include a single layer. The second region 352 including a single layer may be referred to as including only a single conductive layer. The second region 352 may extend from the first region 351 in a direction (e.g., the −y direction) facing the second housing part 220. Unlike the first region 351 including the plurality of layers, since the second region 352 includes only the single layer, thickness of the second region 352 may be thinner than thickness of the first region 351. The single layer of the second region 352 may be a layer in which a layer disposed at the outermost portion among the plurality of layers of the first region 351 is extended.

According to an embodiment, the battery 361 may store power. The battery 361 may be a rechargeable secondary battery. The battery 361 may be configured to supply the power to an electronic component of the electronic device 101 by being controlled by a power management module (e.g., the power management module 188 of FIG. 1).

A charging capacity in which the battery 361 may store may be determined based on a size of the battery 361. As the size of the battery 361 increases, the charging capacity that may be stored in the battery 361 may increase. According to an embodiment, since the electronic device 101 includes components (e.g., the driving mechanism 300) for a movement of the second housing part 220, an internal space for the battery 361 may be limited. As the internal space for the battery 361 is limited, the size of the battery 361 included in the electronic device 101 may be reduced, and thus the charging capacity of the battery 361 may be insufficient. Unlike an electronic device including a bar type housing that is not deformed, since the electronic device 101 according to an embodiment consumes power to cause the movement of the second housing part 220, an internal space for the battery 361 may be required to secure the charging capacity of the battery 361.

According to an embodiment, in the electronic device 101, the driving mechanism 300 may be positioned to be biased to a side from a central region rather than the central region in the housing 201, in order to secure the internal space to dispose the battery 361. As the driving mechanism 300 is positioned to be biased to the side of the housing 201, the internal space to dispose the battery 361 in the housing 201 may be secured, and thus the size of the battery 361 may be increased.

According to an embodiment, the first housing part 210 may include a first edge portion 210a and a second edge portion 210b. The first edge portion 210a and the second edge portion 210b may be edge portions of the first housing part 210 parallel to the direction (e.g., the first direction 261 and/or the second direction 262) of the movement of the second housing part 220. The second edge portion 210b may be opposite to the first edge portion 210a. According to an embodiment, the actuator 310 may be disposed closer to any one among the first edge portion 210a and the second edge portion 210b. For example, the actuator 310 may be disposed closer to the first edge portion 210a among the first edge portion 210a and the second edge portion 210b. A distance between the first edge portion 210a and the actuator 310 may be closer than a distance between the second edge portion 210b and the actuator 310.

According to an embodiment, the second housing part 220 may include a third edge portion 220a and a fourth edge portion 220b. The third edge portion 220a may be at least partially coupled to the first edge portion 210a of the first housing part 210. The fourth edge portion 220b may be at least partially coupled to the second edge portion 210b of the first housing part 210. The fourth edge portion 220b may be opposite to the third edge portion 220a. When the second housing part 220 is moved in the first direction 261 or the second direction 262, the third edge portion 220a may be moved along at least a portion of the first edge portion 210a, and the fourth edge portion 220b may be moved along at least a portion of the second edge portion 210b. According to an embodiment, the rack gear 320 may be disposed closer to the third edge portion 220a among the third edge portion 220a and the fourth edge portion 220b.

According to an embodiment, as the actuator 310 is adjacent to the first edge portion 210a and the rack gear 320 is adjacent to the third edge portion 220a, the rack gear 320 may be positioned next to the actuator 310 in the first state of the electronic device 101. As illustrated in FIG. 3A, when the electronic device 101 is in the first state, the rack gear 320 may be disposed next to the actuator 310. As the actuator 310 and the rack gear 320 are disposed adjacent to each other, the space to dispose the battery 361 inside the housing 201 may be secured. Since the first rotation axis 301 of the actuator 310 is parallel to the direction (e.g., the first direction 261 and/or the second direction 262) of the movement of the second housing part 220, the driving mechanism 300 may be positioned to be biased to the side of the housing 201. Since the driving mechanism 300 is positioned to be biased to the side of the housing 201, the space to dispose the battery 361 inside the housing 201 may be secured. In case that the first rotation axis 301 of the actuator 310 is not parallel to the direction of the movement of the second housing part 220 and is perpendicular to the direction of the movement, since the actuator 310 is positioned perpendicular to the rack gear 320, the space to dispose the battery 361 may be reduced due to the space occupied by the actuator 310. As the space to dispose the battery 361 is secured inside the housing 201, the battery 361 may have a relatively large size.

According to an embodiment, the battery 361 may be disposed in the first housing 210. The battery 361 may at least partially occupy a space between the actuator 310 and the second edge portion 210b of the first housing part 210 in the first housing 210. For example, the battery 361 may have a width less than the distance between the actuator 310 and the second edge portion 210b.

As the size of the battery 361 increases, a size of the printed board assembly 350 may be reduced. Since electronic components are disposed on the printed board assembly 350, when the size of the printed board assembly 350 is reduced, an area of the printed board assembly 350 to dispose the electronic components may be insufficient. According to an embodiment, the battery 361 and the printed board assembly 350 may at least partially overlap to secure the size of the battery 361 and the area of the printed board assembly 350.

According to an embodiment, the battery 361 may at least partially overlap the second region 352 of the printed board assembly 350. The battery 361 may be disposed on the first region 351 among the first region 351 and the second region 352. When the battery 361 is viewed from above, the battery 361 may have a length at least partially overlapping the second region 352 among the first region 351 and the second region 352. For example, at least a portion of the battery 361 may be disposed over (e.g., a +z direction) the second region 352. The first region 351 may not overlap the battery 361, and the at least a portion of the second region 352 may be disposed below (e.g., a −z direction) the battery 361. Since the thickness of the second region 352 including only the single layer is thinner than the thickness of the first region 351 including the plurality of layers, even when the at least a portion of the second region 352 overlaps the battery 361, an increase in thickness of the electronic device 101 may not be significant. As the second region 352 at least partially overlaps the battery 361, the area of the printed board assembly 350 to dispose the electronic components may be secured. For example, a radio frequency (RF) module (e.g., RF integrated circuitry (RFIC) module and a RF front end (RFFE) module) may be disposed on the second region 352, but it is not limited thereto.

According to an embodiment, as the driving mechanism 300 is disposed to be biased to the side of the housing 201, not only may the size of the battery 361 be increased, but a space to dispose other electronic components may be secured. Since the width of the battery 361 is less than the distance between the actuator 310 and the second edge portion 210b, a space may be secured between the third edge portion 220a and the battery 361, in the first state of the electronic device 101. Other electronic components may be disposed in the space between the third edge portion 220a and the battery 361.

For example, the electronic device 101 may include the one or more speakers configured to provide an audio signal. The one or more speakers may include a diaphragm configured to emit the audio signal by vibrating, a voice coil causing the vibration of the diaphragm, and a permanent magnet for forming a magnetic field. For example, the one or more speakers may include the first speaker 362 disposed in the first housing part 210 and the second speaker 363 disposed in the second housing part 220. The first speaker 362 in the first housing part 210 may be disposed on the first region 351 of the printed board assembly 350. The second speaker 363 in the second housing part 220 may be disposed adjacent to the rack gear 320. The second speaker 363 being disposed adjacent to the rack gear 320 may be referred to as a virtual line extending from the rack gear 320 passing through the second speaker 363, or the second speaker 363 being positioned around the virtual line. As the second speaker 363 is disposed in the space between the third edge portion 220a and the battery 361, the electronic device 101 may include a speaker disposed in the second housing part 220. The electronic device 101 may provide a rich sound field effect by providing a stereophonic sound using the first speaker 362 and the second speaker 363.

For example, the electronic device 101 may include a connection terminal 364 (e.g., the connection terminal 178 of FIG. 1) disposed in the second housing part 220. The connection terminal 364 may include a connector that may be physically connected to a terminal of an external electronic device. The connector may be connected to the flexible printed board assembly 350 for providing an electrical connection to the printed board assembly 350. The connection terminal 364 in the second housing part 220 may be disposed adjacent to the rack gear 320. The connection terminal 364 being disposed adjacent to the rack gear 320 may be referred to as the virtual line extending from the rack gear 320 passing through the connection terminal 364, or the connection terminal 364 being positioned around the virtual line. As the connection terminal 364 is disposed in the space between the third edge portion 220a and the battery 361, the electronic device 101 may include a connection terminal disposed in the second housing part 220. The connection terminal 364 disposed in the second housing part 220 may enable an electrical connection with the external electronic device regardless of the state of the electronic device 101. For example, in case that the connection terminal 364 is disposed in the first housing part 210 due to lack of a space in the second housing part 220 for arranging the connection terminal 364, the connection terminal 364 should be disposed in a portion of the first housing part 210 that is not covered by the second housing part 220 in the first state, so that a position where the connection terminal 364 may be disposed may limited. According to an embodiment, the connection terminal 364 disposed in the second housing part 220 may be always exposed to the outside independently of the state of the electronic device 101.

According to an embodiment, the electronic device 101 may secure a space inside the housing 201 through the actuator 310 and the rack gear 320 disposed parallel to each other. As the space is secured, the size of the battery 361 may be increased. As the size of the battery 361 increases, the charging capacity of the battery 361 may increase. As a non-limiting example, other electronic components (e.g., the second speaker 363 and/or the connection terminal 364) may be additionally disposed in the second housing part 220. According to an embodiment, the electronic device 101 may efficiently use the internal space of the housing 201.

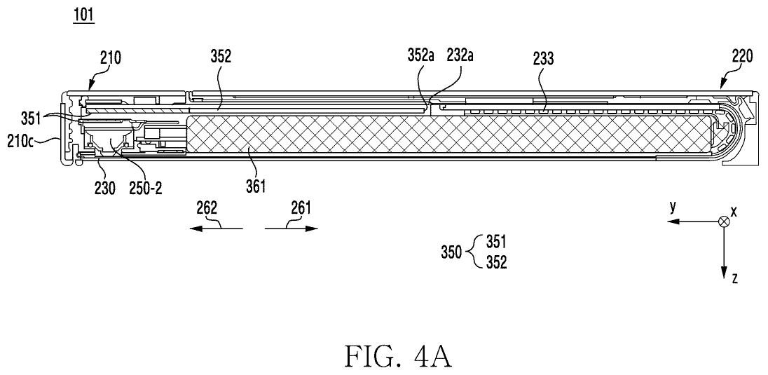

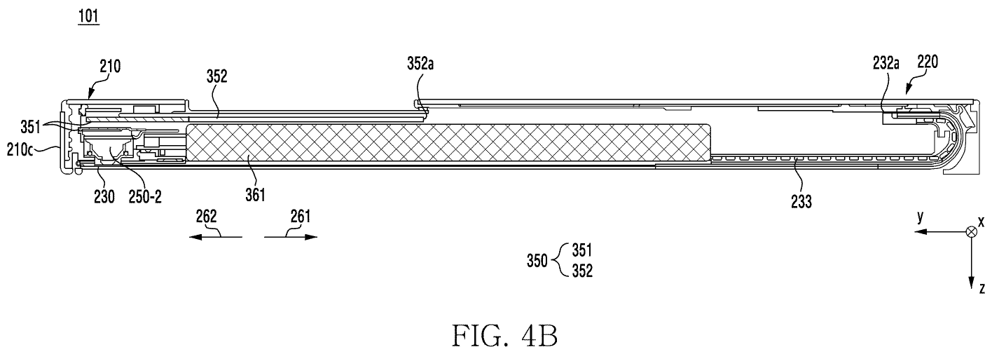

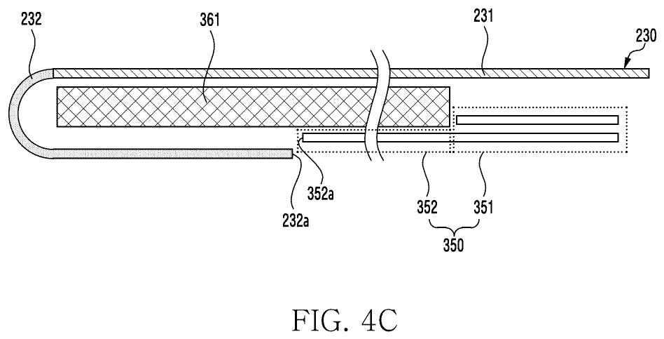

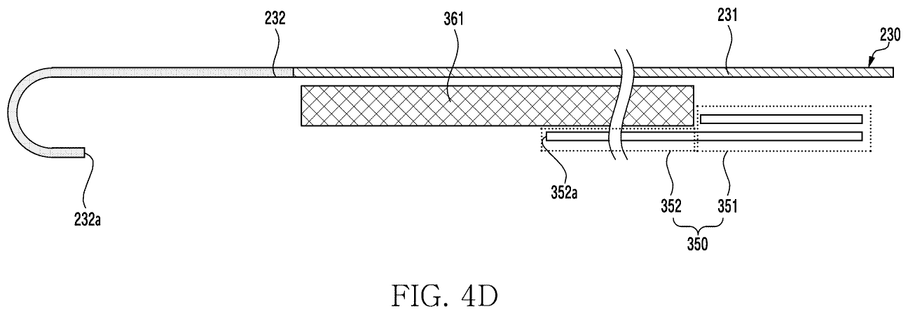

FIG. 4A is a cross-sectional view of an electronic device according to an embodiment cut along line A-A′ of FIG. 3A. FIG. 4B is a cross-sectional view of an electronic device according to an embodiment cut along line B-B′ of FIG. 3B. FIG. 4C illustrates a printed board assembly, a battery, and a flexible display of FIG. 4A. FIG. 4D illustrates a printed board assembly, a battery, and a flexible display of FIG. 4B.

In a first state illustrated in FIG. 4A, a second housing part 220 may be movable in a first direction 261 among the first direction 261, which moves away from a first housing part 210, and a second direction 262, which approaches the first housing part 210. The second housing part 220 may move in the first direction 261, which moves away from the first housing part 210, based on at least a portion of a user input received in the first state. When the second housing part 220 moves to the maximum in the first direction 261, an electronic device 101 may be in a second state illustrated in FIG. 4B. In the first state illustrated in FIG. 4B, the second housing part 220 may be movable in the second direction 262 among the first direction 261 and the second direction 262. The above-described driving mechanism (e.g., the driving mechanism 300 of FIG. 3A) may be configured to provide the first state, the second state, and a plurality of intermediate states between the first state and the second state.

Referring to FIGS. 4A and 4B, a printed board assembly 350 and a battery 361 may be disposed in the first housing part 210. Even when the second housing part 220 is moved in the first direction 261 or the second direction 262, a position of the printed board assembly 350 and the battery 361 disposed in the first housing part 210 may be fixed. The printed board assembly 350 may be adjacent to a fifth edge portion 210c of the first housing part 210. An end portion 352a of a second region 352 may face an opposite of the fifth edge portion 210c. The electronic device 101 may include a support 233 including a plurality of bars for supporting a flexible portion 232. A shape of the support 233 may be deformed based on a state of the electronic device 101.

Referring to FIG. 4C, according to an embodiment, the electronic device 101 may include a flexible display 230. The flexible display 230 may include a planar portion 231 and a flexible portion 232.

For example, the planar portion 231 may be disposed on the first housing part 210. The planar portion 231 may be substantially flat, independently of the state of the electronic device 101. The planar portion 231 may be visible from the outside of the electronic device 101, independently of the state of the electronic device 101. The planar portion 231 may include the first display region 230a of FIG. 2B.

For example, the flexible portion 232 may extend from the planar portion 231. The flexible portion 232 may be configured to be at least partially inserted into the second housing part 220 or extracted from the inside of the second housing part 220 based on a movement of the second housing part 220. As illustrated in FIG. 4C, in the first state, the flexible portion 232 may be at least partially disposed in the second housing part 220, or at least a portion of the flexible portion 232 may be disposed outside the second housing part 220. In the first state, the flexible portion 232 disposed in the second housing part 220 may not be visible from the outside the electronic device 101. The flexible portion 232 may be at least partially bent in the second housing part 220.

Referring to FIG. 4D, in the second state, the flexible portion 232 may be at least partially extracted from the inside of the second housing part 220. In the second state, the flexible portion 232 extracted to the outside of the second housing part 220 may be visible from the outside of the electronic device 101. The flexible portion 232 may include the second display region 230b of FIG. 2B.

FIG. 5A illustrates a printed board assembly and a battery of an electronic device according to an embodiment. FIG. 5B illustrates a flexible display and a printed circuit board of an electronic device according to an embodiment in a first state.

Referring to FIG. 5A, a printed board assembly 350 may include a first region 351 and a second region 352.

For example, the first region 351 may include a plurality of electrically connected layers. For example, the first region 351 may include a first layer 510, a second layer 520, and/or a third layer 530 that are laminated to each other, but it is not limited thereto. The first layer 510, the second layer 520, and the third layer 530 may be electrically connected to each other.

For example, the second region 352 may include a single layer. For example, the single layer in the second region 352 may be implemented in a form in which the first layer 510 disposed at an outermost portion in the first region 351 extends outside the first region 351, but it is not limited thereto.

According to an embodiment, the second region 352 of the printed board assembly 350 and a battery 361 may at least partially overlap each other. When the battery 361 is viewed from above, the battery 361 may at least partially overlap the second region 352 of the printed board assembly 350. For example, at least a portion of the second region 352 may be disposed below (e.g., a −z direction) the battery 361. In case that the printed board assembly 350 does not include the second region 352, an area of the printed board assembly 350 to dispose electronic components of an electronic device 101 may be insufficient. As the second region 352 including the single layer is formed below the battery 361, the area of the printed board assembly 350 may be increased. Even when a length of the battery 361 increases and overlaps the printed board assembly 350, since the battery 361 overlaps the second region 352 including only the single layer, an amount of total thickness increase of the electronic device 101 may be relatively small.

Referring to FIG. 5B, in the first state, an end portion 352a of the second region 352 may be spaced apart from a flexible portion 232 of a flexible display 230. For example, when the electronic device 101 changes from a second state to the first state, an end portion 232a of the flexible portion 232 spaced apart from a planar portion 231 may be moved to approach the printed board assembly 350. In the first state, the end portion 232a of the flexible portion 232 and the end portion 352a of the second region 352 may be closest to each other, but may be spaced apart without contacting each other. As the end portion 232a of the flexible portion 232 and the end portion 352a of the second region 352 are spaced apart from each other, a gap may be formed between the end portions 232a and 352a. A length of the second region 352 may have a length that does not contact the end portion 232a of the flexible portion 232 in the first state. In case that the length of the second region 352 is too long, the end portion 352a of the second region 352 may may be contacted with the end portion 232a of the flexible portion 232. In case that the end portions 232a and 352a are contacted with each other, damage to the flexible display 230 and/or the printed board assembly 350 may be caused. According to an embodiment, the damage may be reduced and/or prevented, by separating the end portion 352a of the second region 352 from the end portion 232a of the flexible portion 232.

FIGS. 6A and 6B illustrate a driving mechanism and a bracket of an electronic device according to an embodiment. FIG. 6C illustrates a bracket according to an embodiment.

Referring to FIGS. 6A and 6B, according to an embodiment, an electronic device 101 may guide translation (e.g., a y direction or a −y direction) of a rack gear 320, and may include a bracket 600 for protecting one or more gears 340 and a pinion gear 330. The bracket 600 may be fixed to a first housing part 210. For example, the bracket 600 may include a through hole 640 into which a screw fixed to the first housing part 210 is inserted. The screw may be inserted into the through hole 640 and then coupled to the first housing part 210, thereby fixing the bracket 600 at a designated position in the first housing part 210. However, a configuration and a method of fixing the bracket 600 in the first housing part 210 are not limited thereto.

For example, the one or more gears 340 connected to an actuator 310, and the pinion gear 330 engaged with the one or more gears 340 may be at least partially surrounded by the bracket 600. The bracket 600 may protect the one or more gears 340 and the pinion gear 330 by at least partially surrounding the one or more gears 340 and the pinion gear 330.

For example, the bracket 600 may include a guide rail 601 for guiding the translation of the rack gear 320. The guide rail 601 may be contacted with at least a portion of the rack gear 320 such that a direction of the movement of the rack gear 320 is aligned with a first direction 261 and/or a second direction 262. The rack gear 320 may be moved in the first direction 261 or the second direction 262 in a state of being at least partially in contact with the guide rail 601. When the rack gear 320 is moved, the guide rail 601 may be configured to provide a stable movement of the rack gear 320 by reducing shaking of the rack gear 320.

According to an embodiment, the guide rail 601 may include a first side wall 610 and a second side wall 620. The first side wall 610 may be contacted with a portion of a side of the rack gear 320. The second side wall 620 may be contacted with a portion of another side of the rack gear 320 opposite to the side. The first side wall 610 and the second side wall 620 may face each other with the rack gear 320 interposed therebetween. The one or more gears 340 for transmitting driving force from the actuator 310 to the pinion gear 330 may be closer to the second side wall 620, among the first side wall 610 and the second side wall 620.

Referring to FIGS. 6A, 6B, and 6C, the bracket 600 may include a third side wall 630. The third side wall 630 may be connected to the second side wall 620, and may surround the one or more gears 340. For example, the third side wall 630 may be connected to a point of the second side wall 620 and another point of the second side wall 620 spaced apart from the point to surround a space where the one or more gears 340 are positioned. The third side wall 630 may include one or more portions bent to surround the one or more gears 340.

According to an embodiment, a portion of the second side wall 620 may include an opening region 621. The opening region 621 may be formed by removing (or omitting) the portion of the second side wall 620. The one or more gears 340 may be connected to the pinion gear 330 engaged with the rack gear 320 through the opening region 621. A gap between the actuator 310 and the rack gear 320 may be reduced by forming the opening region 621 in the second side wall 620.

In case that the opening region 621 is not formed in the second side wall 620, the one or more gears 340 may be further spaced apart from the second side wall 620 in a direction away from the rack gear 320 by more than or equal to thickness of the second side wall 620 so as not to interfere with the second side wall 620. For example, a second gear 342 connected to the pinion gear 330 should be spaced apart from the second side wall 620 so as not to interfere with the second side wall 620. As the second gear 342 is further spaced apart from the second side wall 620, a first gear 341 engaged with the second gear 342 is also further spaced apart from the second side wall 620. Since the actuator 310 is connected to the first gear 341, the actuator 310 is spaced further apart from the rack gear 320 as the first gear 341 is spaced further apart. In case that the second side wall 620 does not include the opening region 621, the gap between the rack gear 320 and the actuator 310 increases. As the gap between the rack gear 320 and the actuator 310 is reduced, a space occupied by the driving mechanism 300 in a housing (e.g., the housing 201 of FIG. 3A) increases.

According to an embodiment, since the second side wall 620 includes the opening region 621, the one or more gears 340 may be positioned closer to the second side wall 620 than in the case. Since the opening region 621 is a portion where the second side wall 620 is removed (or omitted), even when the second gear 342 is closer to the second side wall 620, the second gear 342 may not interfere with the second side wall 620. In case that the second gear 342 is positioned to be closer to the second side wall 620, the first gear 341 engaged with the second gear 342 may also be closer to the second side wall 620. The actuator 310 connected to the first gear 341 may be closer to the rack gear 320. In case that the second side wall 620 includes the opening region 621, the gap between the rack gear 320 and the actuator 310 may be reduced. As the gap between the rack gear 320 and the actuator 310 is reduced, the space occupied by the driving mechanism 300 in the housing 201 may be reduced. In case that the space occupied by the driving mechanism 300 is reduced, since the space in the housing 201 may be additionally secured, the size (e.g., width) of the battery 361 may be increased.

According to an embodiment, the first gear 341 may be connected to the actuator 310 through a first shaft (e.g., the first shaft 303 of FIG. 6A). The second gear 342 may be connected to the pinion gear 330 through a second shaft 304. As described above, the first shaft 303 may be disposed perpendicular to the second shaft 304. Based on an operation of the actuator 310, the first shaft 303 may be rotated, and the first gear 341 may be rotated by the rotation of the first shaft 303. When the first gear 341 is rotated, the second gear 342 including second teeth 342a engaged with first teeth 341a of the first gear 341 may also be rotated. As the second gear 342 is rotated, the second shaft 304 may be rotated. Since the second shaft 304 is connected to the pinion gear 330, rotation of the pinion gear 330 may be caused. The rotation of the pinion gear 330 may cause a movement of the rack gear 320. The first shaft 303 may be connected to each of the actuator 310 and the first gear 341, and since the bracket 600 surrounds the first gear 341, the first shaft 303 may penetrate the bracket 600. Since the second shaft 304 is connected to each of the second gear 342 and the pinion gear 330, and the bracket 600 surrounds the second gear 342 and the pinion gear 330, the second shaft 304 may penetrate the bracket 600. The bracket 600 may include openings for the first shaft 303 and the second shaft 304.

According to an embodiment, the third side wall 630 may include a first portion 631, a second portion 632, and a third portion 633. The first portion 631 may extend substantially perpendicular to the second side wall 620. The second portion 632 may extend substantially perpendicular to an end portion of the first portion 631. The third portion 633 may extend perpendicular to an end portion of the second portion 632 to face the first portion 631. The first portion 631, the second portion 632, and the third portion 633 may surround the one or more gears 340 together with the second side wall 620. The second portion 632 may be substantially parallel to the second side wall 620 and/or the first side wall 610.

According to an embodiment, the first portion 631 may include a first opening (e.g., the first opening 651 of FIG. 6C) through which the first shaft 303 passes. The first shaft 303 may be connected to the first gear 341 by passing through a first opening 651 from the actuator 310. The second portion 632 may include a second opening (e.g., the second opening 652 of FIG. 6C) through which the second shaft 304 passes. A portion of the second shaft 304 passing through a second opening 652 may be a portion extending from the second gear 342 in a direction away from the pinion gear 330. The first side wall 610 may include a third opening (e.g., the third opening 653 of FIG. 6C) through which the second shaft 304 passes. A portion of the second shaft 304 passing through a third opening 653 may be a portion extending from the pinion gear 330 in a direction away from the second gear 342.

Since the first shaft 303 and the second shaft 304 are rotated to cause translation of the rack gear 320, friction between the first shaft 303 and the bracket 600, and friction between the second shaft 304 and the bracket 600, may occur. The friction may cause damage to the first shaft 303, the second shaft 304, and the bracket 600. According to an embodiment, the bracket 600 may include bearings for reducing the friction. For example, the bearings may include an outer wheel, an inner wheel, and a ball bearing including a plurality of balls between the inner wheel and the outer wheel, but it is not limited thereto.

According to an embodiment, the bracket 600 may include a first bearing 661, a second bearing 662, and a third bearing 663. For example, the first bearing 661 may be disposed in the first opening 651, and may be contacted with an outer surface of the first shaft 303 passing through the first opening 651. For example, the second bearing 662 may be disposed in the second opening 652, and may be contacted with an outer surface of the second shaft 304 passing through the second opening 652. For example, the third bearing 663 may be disposed in the third opening 653, and may be contacted with the outer surface of the second shaft 304 passing through the third opening 653.

For example, the first bearing 661 may be a ball bearing including the outer wheel coupled to a periphery of the first opening 651, the inner wheel in contact with the outer surface of the first shaft 303, and the plurality of balls between the outer wheel and the inner wheel. When the first shaft 303 is rotated, the inner wheel in contact with the outer surface of the first shaft 303 may be rotated together with the plurality of balls. As the inner wheel in contact with the outer surface of the first shaft 303 rotates together with the first shaft 303, frictional force by the first shaft 303 may be reduced. The reduction of the frictional force may reduce damage to the bracket 600 and the first shaft 303. The above description of the first bearing 661 may be applied substantially equally to the second bearing 662 and the third bearing 663. As an example of the bearing, a ball bearing has been described, but the bearings according to an embodiment are not limited thereto.

FIG. 7A is a side view of a driving mechanism illustrated in FIG. 6A. FIG. 7B illustrates a driving mechanism in which teeth of a rack gear are disposed to face a rear of an electronic device. FIG. 7C is a side view of a driving mechanism illustrated in FIG. 7B.

Referring to FIG. 7A, in case of a driving mechanism 300, a rack gear 320 may be disposed such that teeth 320a of the rack gear 320 engaged with teeth 330a of a pinion gear 330 face a direction (e.g., +z direction) toward a front of an electronic device 101. For example, the teeth 320a of the rack gear 320 illustrated in FIG. 7A may face the front of the electronic device 101. In case that the teeth 320a of the rack gear 320 face the front of the electronic device 101, electronic components of the electronic device 101 may be disposed over (e.g., the +z direction) the rack gear 320. However, it is not limited thereto, and the teeth 320a of the rack gear 320 may be disposed opposite to a structure illustrated in FIG. 7A.

Referring to FIGS. 7B and 7C, the rack gear 320 may be disposed such that the teeth 320a of the rack gear 320 face a direction (e.g., a −z direction) toward a rear of the electronic device 101. For example, the teeth 320a of the rack gear 320 illustrated in FIG. 7B may face the rear of the electronic device 101. In case that the teeth 320a of the rack gear 320 face the rear of the electronic device 101, the electronic components of the electronic device 101 may be disposed below (e.g., the −z direction) the rack gear 320.

According to an embodiment, in a first state of the electronic device 101, the rack gear 320 may be disposed next to an actuator 310. In case of examples of the driving mechanism 300 described above, the rack gear 320 is illustrated to be positioned on a side (e.g., a −x direction) of the actuator 310, but positions of the rack gear 320 and the actuator 310 may be exchanged each other. For example, although not illustrated, the rack gear 320 may be positioned on another side (e.g., +x direction) of the actuator 310.

As described above, arrangement structures of the rack gear 320 and the actuator 310 may vary. The teeth 320a of the rack gear 320 may face the front or the rear of the electronic device 101, and the positions of the rack gear 320 and the actuator 310 may be exchanged each other. According to a structure, a size, and a position of components disposed in the electronic device 101, and the like, arrangement structures of the driving mechanism 300 may be implemented in various ways.

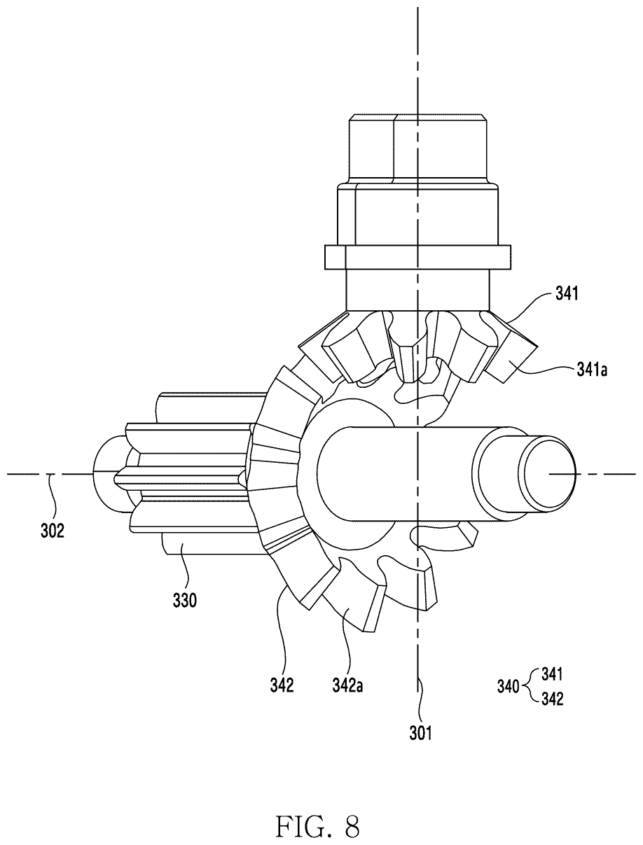

FIG. 8 illustrates one or more gears according to an embodiment.

Referring to FIG. 8, one or more gears 340 may be provided to transmit driving force from an actuator (e.g., the actuator 310 of FIG. 3A). For example, the one or more gears 340 may include a first gear 341 that rotates with respect to a first rotation axis 301 of an actuator (e.g., the actuator 310 of FIG. 3A) and a second gear 342 that rotates with respect to a second rotation axis 302 perpendicular to the first rotation axis 301.

According to an embodiment, the first gear 341 may include first teeth 341a. The second gear 342 may include second teeth 342a engaged with the first teeth 341a. Since the first gear 341 and the second gear 342 transmit the driving force from an actuator 310 to a pinion gear 330, efficiency of the actuator 310 may be reduced compared to when the actuator is directly connected to the pinion gear 330.

The reduction of the efficiency of the actuator 310 may cause a reduction in propulsion force of a rack gear (e.g., the rack gear 320 of FIG. 3A). According to an embodiment, in case that the actuator 310 of a driving mechanism 300 has the same revolutions per minute (RPM) as the actuator according to a comparative example of being directly connected to the pinion gear 330, the propulsion force of a rack gear 320 may be reduced, thereby reducing speed of a movement of the rack gear 320. According to an embodiment, since the actuator 310 should additionally perform work to rotate the first gear 341 and the second gear 342, efficiency may be reduced by a gear ratio according to the first teeth 341a and the second teeth 342a, compared to when the actuator 310 is directly connected to the pinion gear 330. Since speed of a movement of a second housing part (e.g., the second housing part 220 of FIG. 3A) may be reduced when the speed of the movement of the rack gear 320 is reduced, usability of the electronic device (e.g., the electronic device 101 of FIG. 3A) may deteriorate.

According to an embodiment, in order to compensate for the reduction of the propulsion force of the rack gear 320 caused by addition of the one or more gears 340, the actuator 310 may have higher RPM than an actuator according to the comparative example. For example, the RPM of the actuator 310 may be determined based on the gear ratio according to the first teeth 341a and the second teeth 342a.

For example, it is assumed that first RPM of the actuator according to the comparative example, which is directly connected to the pinion gear 330, is X. Second RPM of the actuator 310 according to an embodiment, which is operatively (or indirectly) connected to the pinion gear 330 using the first gear 341 and the second gear 342, may be increased from x by the gear ratio of the first teeth 341a and the second teeth 342a. For example, in case that the gear ratio of the first teeth 341a and the second teeth 342a is a:b, the second RPM may be referred to as (b/a)×X. For example, the gear ratio between the first teeth 341a and the second teeth 342a may be 8:11, and in this case, the second RPM may be set (11/8) times higher than the first RPM. According to an embodiment, as the RPM of the actuator 310 is set based on the gear ratio of the first teeth 341a and the second teeth 342a, the propulsion force of the rack gear 320 may be formed substantially the same as in a case according to the comparative example.

According to an embodiment, the one or more gears 340 may include a bevel gear. For example, the first gear 341 and the second gear 342 may be the bevel gear. The bevel gear, which is a gear that transmits rotation in case that two axes intersect, may increase torque by reducing rotational speed of an input axis (e.g., the first rotation axis 301). In case that the one or more gears 340 is the bevel gear, teeth 320a of the rack gear 320 may face a front or a rear of an electronic device 101. As described above, since the torque is increased, the propulsion force of the rack gear 320 may be reduced. As described above, according to an embodiment, the actuator 310 may be set to have RPM to compensate for the reduction of the propulsion force caused by the bevel gear.

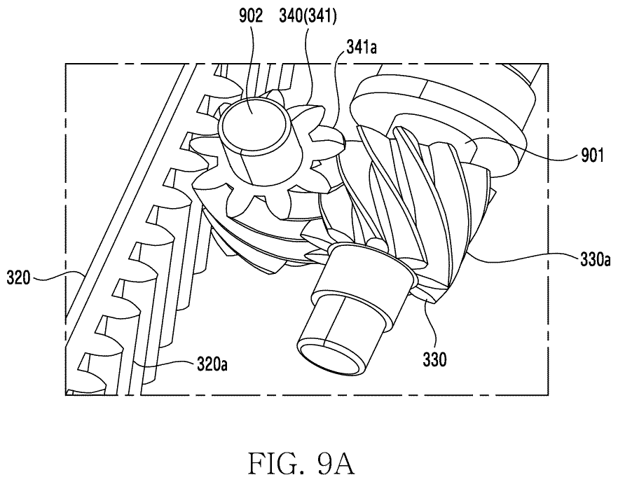

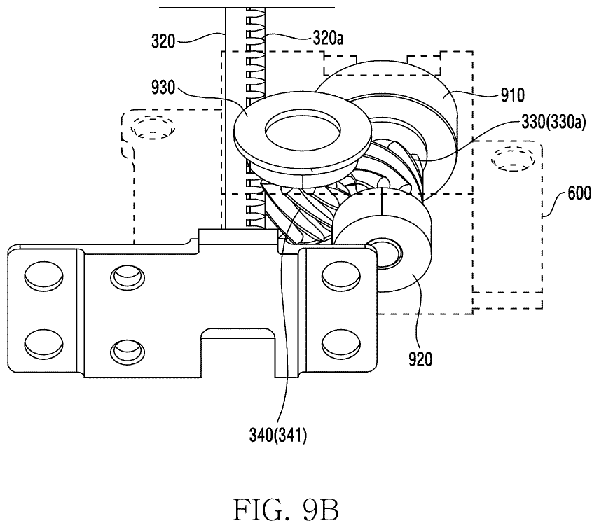

FIG. 9A illustrates one or more gears according to an embodiment. FIG. 9B illustrates a portion of a driving mechanism including the one or more gears illustrated in FIG. 9A.

Referring to FIG. 9A, a pinion gear 330 and one or more gears 340 may include a helical gear. For example, the one or more gears 340 may be the helical gear. The helical gear is a gear in which teeth extend in a spiral. In case that the pinion gear 330 and the one or more gears 340 are the helical gear, a structure of a driving mechanism 300 may be changed. In case that the pinion gear 330 and the one or more gears 340 are the helical gear, teeth 320a of the rack gear 320 may face a lateral surface (e.g., the first edge portion 210a, the second edge portion 210b, the third edge portion 220a, or the fourth edge portion 220b of FIG. 3A) between a front and a rear of an electronic device (e.g., the electronic device 101 of FIG. 3A).

Referring to FIGS. 9A and 9B, the pinion gear 330 may be a helical pinion gear including teeth extending in the spiral. The pinion gear 330 may be connected to the actuator 310. The rack gear 320 may be disposed such that the teeth 320a of the rack gear 320 face the pinion gear 330. For example, the teeth 320a of the rack gear 320 may face the actuator 310. A first gear 341, which is a helical gear, may be disposed between the rack gear 320 and the pinion gear 330. First teeth 341a of the first gear 341 may be engaged with the teeth 320a of the rack gear 320 and teeth 330a of the pinion gear 330, respectively. The rack gear 320, the pinion gear 330, and the first gear 341 may all be the helical gear having the teeth extending in the spiral. The teeth may have a certain inclination (e.g., an inclination of approximately 45 degrees). A bracket 600 may fix and protect the rack gear 320, the pinion gear 330, and the first gear 341. Bearings may be disposed inside the bracket 600 to reduce friction caused by rotation of shafts. In this case, the bracket 600 may include a first bearing 910 and a second bearing 920 for a shaft (e.g., the shaft 901 of FIG. 9A) connected to the pinion gear 330, and a third bearing 930 and a fourth bearing (not illustrated) for a shaft (e.g., the shaft 902 of FIG. 9B) connected to the first gear 341.

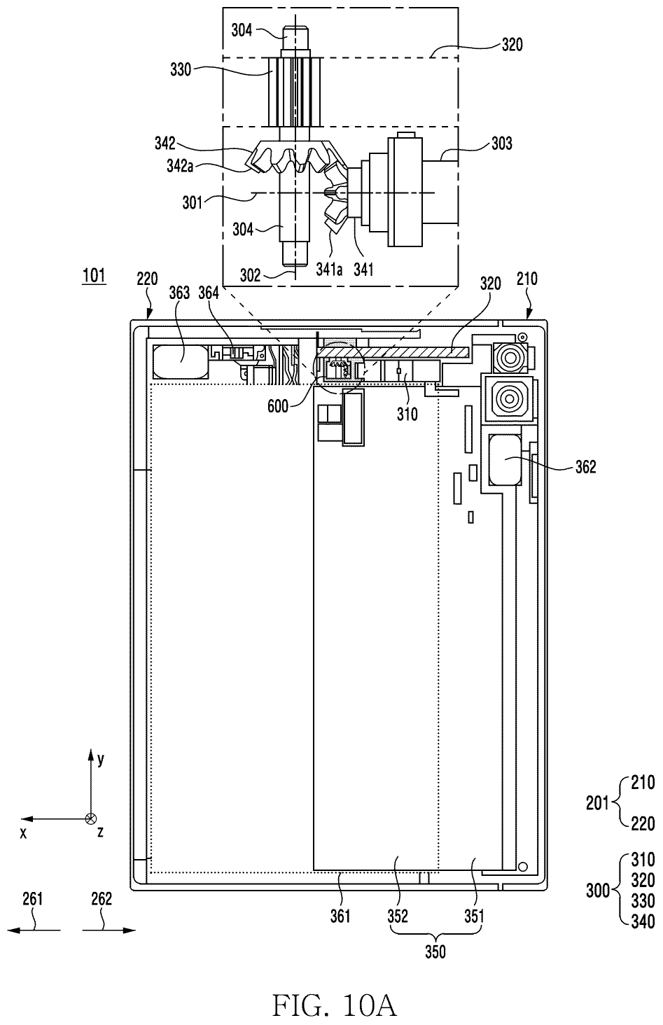

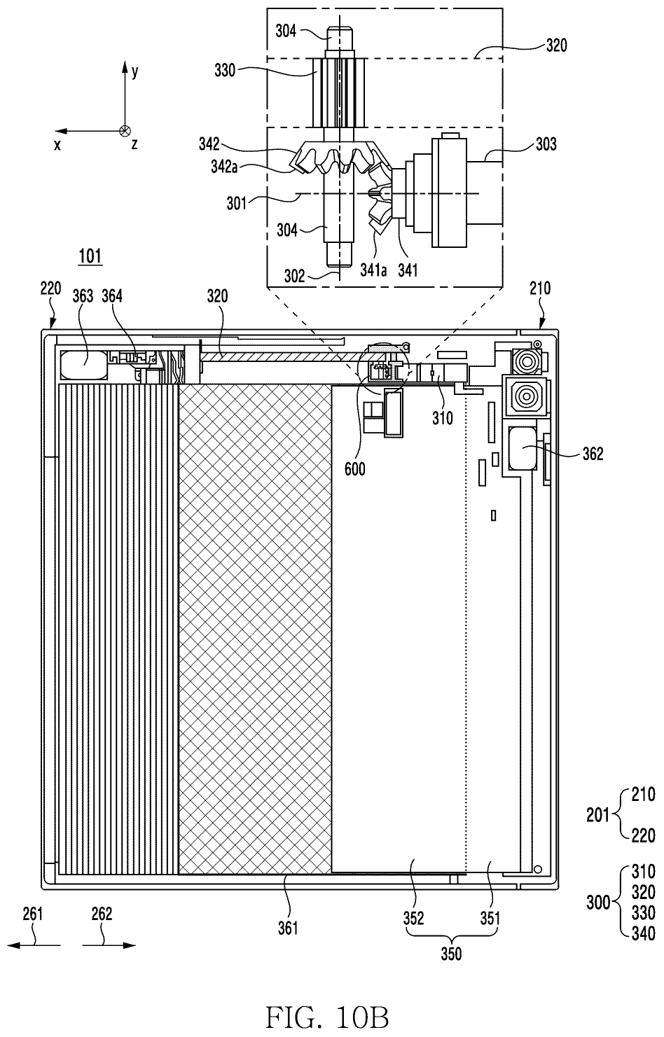

FIG. 10A illustrates an interior of an electronic device according to an embodiment in a first state. FIG. 10B illustrates an interior of an electronic device according to an embodiment in a second state. In the above-described drawings, an electronic device 101 is illustrated as an electronic device having a structure that moves in a direction parallel to a y-axis, but embodiments are not limited thereto.

Referring to FIGS. 10A and 10B, according to an embodiment, the electronic device 101 may be an electronic device having a structure that moves in a direction parallel to an x-axis. The electronic device 101 illustrated in FIGS. 10A and 10B may be substantially the same as the electronic device 101 described above, except that a direction of a movement of a second housing part 220 is parallel to the x-axis. The same reference numerals are assigned to the same components, and redundant descriptions may be omitted.

According to an embodiment, the electronic device 101 may include a housing 201 including a first housing part 210 and the second housing part 220. The second housing part 220 may be movable with respect to the first housing part 210 in a direction parallel to the x-axis. In a first state of the electronic device 101 illustrated in FIG. 10A, the second housing part 220 may be movable with respect to the first housing part 210 in a first direction 261 among the first direction 261 and a second direction 262. For example, in the first state, the second housing part 220 may not be substantially movable in the second direction 262 with respect to the first housing part 210.

According to an embodiment, a driving mechanism 300 may include an actuator 310, a rack gear 320, a pinion gear 330, and one or more gears 340. The actuator 310 may be disposed to have a first rotation axis 301 parallel to a direction (e.g., an x-axis direction) of a movement of the second housing part 220. The rack gear 320 may extend to be parallel to the direction of the movement of the second housing part 220. The pinion gear 330 may be engaged with the rack gear 320. The one or more gears 340 may be connected to each of the actuator 310 and the pinion gear 330 to be configured to transmit driving force from the actuator 310 to the pinion gear 330. For example, the one or more gears 340 may include a first gear 341 and a second gear 342, but it is not limited thereto. The first gear 341 may rotate with respect to the first rotation axis 301, and the second gear 342 may rotate with respect to a second rotation axis 302 perpendicular to the first rotation axis 301. The driving mechanism 300 may not be disposed in a central region of the housing 201, but may be disposed to be biased to a side of the housing 201.

According to an embodiment, the electronic device 101 may include a battery 361. Since the rack gear 320 and the actuator 310 are disposed to be biased to the side of the housing 201, an internal space of the housing 201 for the battery 361 may be secured. As the internal space for the battery 361 is secured, a size of the battery 361 may be increased. The battery 361 may have a relatively large charging capacity by having a relatively large size.

According to an embodiment, the electronic device 101 may include a printed board assembly 350. The printed board assembly 350 may include a first region 351 including a plurality of layers and a second region 352 including only a single layer. The single layer in the second region 352 may be connected to a layer disposed on an outermost portion of the first region 351 or may be referred to as the same layer.

According to an embodiment, in order to secure the size of the battery 361 and an area of the printed board assembly 350, the battery 361 and the printed board assembly 350 may at least partially overlap. When the battery 361 is viewed from above, the battery 361 may have a length at least partially overlapping the second region 352 among the first region 351 and the second region 352.

As the driving mechanism 300 is disposed to be biased to the side of the housing 201, a space for electronic components may be secured. According to an embodiment, the electronic device 101 may include a first speaker 362 and a second speaker 363. The first speaker 362 may be disposed in the first housing part 210, and the second speaker 363 may be disposed in the second housing part 220. According to an embodiment, the electronic device 101 may include a connection terminal 364 disposed in the second housing part 220.

An electronic device 101 is provided. The electronic device 101 may comprise a housing 201 including a first housing part 210 and a second housing part 220, movably coupled to each other. For example, the second housing part 220 may be movably coupled to the first housing part 210 in a first direction 261 or a second direction 262 opposite to the first direction 261. The electronic device 101 may comprise a driving mechanism 300 configured to cause a movement of the first housing part 210 or a movement the second housing part 220. The electronic device 101 may comprise a printed board assembly 350 disposed in the first housing part 210, and including a first region 351 which is a laminating region of printed circuit boards, and a second region 352 which is a non-laminating region. The electronic device 101 may comprise a battery 361 disposed in the first housing part 210. The driving mechanism 300 may include an actuator 310 having a rotation axis 301 parallel to a direction of the movement of the first housing part 210 or the second housing part 220. The driving mechanism 300 may include a rack gear 320 disposed parallel to the rotation axis 301. The battery 361 may be positioned over the second region 352 among the first region 351 and the second region 352. For example, the rack gear 320 may be coupled to the second housing part 220 and may be extended parallel to the direction (e.g., the first direction 261 and the second direction 262) of the movement of the first housing part 210 or the second housing part 220. For example, the first region 351 may include a plurality of layers. The second region 352 may include a single layer. When the battery 361 is viewed from above, the battery 361 may have a length at least partially overlapping the second region 352 among the first region 351 and the second region 352. According to an embodiment, as the rotation axis 301 of the actuator 310 is disposed parallel to the rack gear 320, an internal space of the housing 201 occupied by the driving mechanism 300 may be reduced. Since the space occupied by the driving mechanism 300 is reduced, the size of the battery 361 may be increased, such that the charging capacity of the battery 361 may be secured. In order to secure an area for mounting electronic components on the printed board assembly 350, a portion of the printed board assembly 350 and the battery 361 may at least partially overlap.

For example, the actuator 310 may be disposed closer to a first edge portion 210a among the first edge portion 210a of the first housing part 210 parallel to the direction of the movement and a second edge portion 210b of the first housing part 210, opposite to the first edge portion 210a. The rack gear 320 may be disposed closer to a third edge portion 220a of the second housing part 220 among the third edge portion 220a at least partially coupled to the first edge portion 210a of the first housing part 210 and a fourth edge portion 220b of the second housing part 220 opposite to the third edge portion 220a. The battery 361 may at least partially occupy a space of the first housing part 210 between the actuator 310 and the second edge portion 210b of the first housing part 210. According to an embodiment, as a width of the battery 361 is increased, the size of the battery 361 may be increased.

For example, the driving mechanism 300 may be configured to provide a first state in which the second housing part 220 is movable in a first direction 261 among the first direction 261 in which the second housing part 220 moves away from the first housing part 210 and a second direction 262 in which the second housing part 220 approaches the first housing part 210, a second state in which the second housing part 220 is movable in the second direction 262 among the first direction 261 and the second direction 262, and a plurality of intermediate states between the first state and the second state. The rack gear 320 may be positioned next to the actuator 310, in the first state. According to an embodiment, as the rack gear 320 is disposed next to the actuator 310, the driving mechanism 300 may be compactly mounted in the housing 201.

For example, the electronic device 101 may further comprise a flexible display 230. The flexible display 230 may include a planar portion 231 disposed on the first housing part 210. The flexible display 230 may extend from the planar portion 231. The flexible display 230 may include a flexible portion 232 configured to be at least partially rolled into the second housing part 220 or to be at least partially extracted from an inside of the second housing part 220, based on a movement of the second housing part 220. According to an embodiment, a size of a display region of the flexible display 230 may be changed based on the movement of the second housing part 220.

For example, the printed board assembly 350 may be adjacent to a fifth edge portion 210c perpendicular to the first edge portion 210a of the first housing part 210 parallel to the direction of the movement (e.g., the first direction 261 and the second direction 262) and spaced apart from the second housing part 220. An end portion 352a of the second region 352 of the printed board assembly 350 facing opposite of the fifth edge portion 210c may be spaced apart from an end 232a portion of the flexible portion 232 positioned in the second housing part 220. According to an embodiment, as the end portion 352a of the second region 352 is spaced apart from the end portion 232a of the flexible portion 232, damage to the printed board assembly 350 and the flexible display 230 may be reduced.

For example, the electronic device 101 may further comprise a bracket 600 including a guide rail 601 to guide translation of the rack gear 320. The driving mechanism 300 may comprise a pinion gear 330, operatively coupled to the actuator 310, configured to rotate based on an operation of the actuator 310, and engaged with the rack gear 320. The driving mechanism 300 may comprise one or more gear 340 connected to each of the actuator 310 and the pinion gear 330 to transmit driving force from the actuator 310 to the pinion gear 330. The guide rail 601 may comprise a first side wall 610 contacted with a portion of a side of the rack gear 320, and a second side wall 620 contacted with a portion of another side of the rack gear 320 opposite to the side of the rack gear, and including an opening region 621 to reduce a gap between the actuator 310 and the rack gear 320. The one or more gears 340 may be closer to the second side wall 620 among the first side wall 610 and the second side wall 620.

For example, the one or more gears 340 may be connected to the pinion gear 330 engaged with the rack gear 320 through the opening region 621.

For example, the bracket 600 may comprise a third side wall 630 connected to the second side wall 620 and surrounding the one or more gears 340.

For example, the one or more gears 340 may comprise a first gear 341 including first teeth 341a. The one or more gears 340 may comprise a second gear 342 including second teeth 342a engaged with the first teeth 341a and configured to cause rotation of the pinion gear 330 based on rotation of the first gear 341. The driving mechanism 300 may comprise a first shaft 303, parallel to the rotation axis 301, connected to each of the actuator 310 and the first gear 341 and configured to rotate based on the operation of the actuator 310. The driving mechanism 300 may comprise a second shaft 304 connected to each of the pinion gear 330 and the second gear 342 and perpendicular to the first shaft 303. The third side wall 630 may comprise a first portion 631 extending perpendicular to the second side wall 620 and including a first opening 651 through which the first shaft 303 passes, a second portion 632 extending perpendicular to an end portion of the first portion 631 and including a second opening 652 through which the second shaft 304 passes, and a third portion 633 extending perpendicular to an end portion of the second portion 632 to face the first portion 631.

For example, the first side wall 610 may include a third opening 653 through which the second shaft 304 passes. The bracket 600 may comprise a first bearing 661 disposed in the first opening 651 and contacted with the first shaft 303. The bracket 600 may comprise a second bearing 662 disposed in the second opening 652 and contacted with the second shaft 304. The bracket 600 may comprise a third bearing 663 disposed in the third opening 653 and contacted with the second shaft 304.

For example, the actuator 310 may have revolutions per minute (RPM) based on a gear ratio according to the first teeth 341a and the second teeth 342a. According to an embodiment, the actuator 310 may have the RPM based on the gear ratio to compensate for a reduction in the propulsion force of the rack gear 320 by one or more gears 340.

For example, the one or more gears is a bevel gear. Teeth 320a of the rack gear 320 may face a front of the electronic device 101 or a rear of the electronic device 101.

For example, the pinion gear 330 and the one or more gears 340 are a helical gear. The teeth 320a of the rack gear 320 may face a lateral surface of the electronic device 101.

For example, the electronic device 101 may further comprise a speaker 363 configured to provide an audio signal and disposed adjacent to the rack gear 320 in the second housing part 220.

For example, the electronic device 101 may further comprise a connection terminal 364 disposed adjacent to the rack gear 320 in the second housing part 220, and connected to a terminal of an external electronic device.

An electronic device 101 is provided. The electronic device 101 may comprise a housing 201 including a first housing part 210 and a second housing part 220 movably coupled to the first housing part 210. The electronic device 101 may comprise a driving mechanism 300 configured to cause a movement of the second housing part 220 relative to the first housing part 210. The driving mechanism 300 may include an actuator 310 disposed in the first housing part 210 to have a rotation axis 301 parallel to a direction of the movement of the second housing part 220. The driving mechanism 300 may include a rack gear 320 coupled to the second housing part 220 and extended parallel to the direction. The driving mechanism 300 may include a pinion gear 330, operatively coupled to the actuator 310, configured to rotate based on an operation of the actuator 310, and engaged with the rack gear 320. The driving mechanism 300 may include one or more gear 340 connected to each of the actuator 310 and the pinion gear 330 to transmit driving force from the actuator 310 to the pinion gear 330. The electronic device 101 may comprise a bracket 600 including a guide rail 601 to guide translation of the rack gear 320. The guide rail 601 may comprise a first side wall 610 contacted with a portion of a side of the rack gear 320, and a second side wall 620 contacted with a portion of another side of the rack gear opposite to the side of rack gear 320, and including an opening region 621 to reduce a gap between the actuator 310 and the rack gear 320. The one or more gears 340 may be closer to the second side wall 620 among the first side wall 610 and the second side wall 620.

For example, the bracket 600 may comprise a third side wall 630 connected to the second side wall 620 and surrounding the one or more gears 340. The one or more gears 340 may comprise a first gear 341 including first teeth 341a. The one or more gears 340 may comprise a second gear 342 including second teeth 342a engaged with the first teeth 341a and configured to cause rotation of the pinion gear 330 based on rotation of the first gear 341. The driving mechanism 300 may comprise a first shaft 303, parallel to the rotation axis, connected to each of the actuator 310 and the first gear 341, and configured to rotate based on the operation of the actuator 310. The driving mechanism 300 may comprise a second shaft 304 connected to each of the pinion gear 330 and the second gear 342 and perpendicular to the first shaft 303. The third side wall 630 may comprise a first portion 631 extending perpendicular to the second side wall 620 and including a first opening 651 through which the first shaft 303 passes, a second portion 632 extending perpendicular to an end portion of the first portion and including a second opening 652 through which the second shaft 304 passes, and a third portion 633 extending perpendicular to an end portion of the second portion 632 to face the first portion 631.

For example, the first side wall 610 may include a third opening 653 through which the second shaft 304 passes. The bracket 600 may comprise a first bearing 661 disposed in the first opening 651 and contacted with the first shaft 303. The bracket 600 may comprise a second bearing 662 disposed in the second opening 652 and contacted with the second shaft 304. The bracket 600 may comprise a third bearing 663 disposed in the third opening 653 and contacted with the second shaft 304.

For example, the electronic device 101 may further comprise a printed board assembly (PBA) 350 disposed in the first housing part 210. The printed board assembly 350 may comprise a first region 351 which is a laminating region of printed circuit boards. The printed board assembly 350 may comprise a second region 352 which is a non-laminating region, extended from the first region 351. The electronic device 101 may further comprise a battery 361 disposed in the first housing part 210. When the battery 361 is viewed from above, the battery 361 may have a length that at least partially overlaps the second region 352 among the first region 351 and the second region 352. For example, the first region 351 may include a plurality of layers laminated on each other, and the second region 352 may include a single layer.

For example, the actuator 310 may be disposed closer to a first edge portion 210a among the first edge portion 210a of the first housing part 210 parallel to the direction and a second edge portion 210b of the first housing part opposite to the first edge portion 210a. The rack gear 320 may be disposed closer to a third edge portion 220a of the second housing part 220 among the third edge portion 220a at least partially coupled to the first edge portion 210a of the first housing part 210 and a fourth edge portion 220b of the second housing part opposite to the third edge portion 220a. The battery 361 may at least partially occupy a space of the first housing part between the actuator 310 and the second edge portion 210b of the first housing part 210.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” or “connected with” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between a case in which data is semi-permanently stored in the storage medium and a case in which the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

It will be appreciated that various embodiments of the disclosure according to the claims and description in the specification can be realized in the form of hardware, software or a combination of hardware and software.

Any such software may be stored in non-transitory computer readable storage media. The non-transitory computer readable storage media store one or more computer programs (software modules), the one or more computer programs include computer-executable instructions that, when executed by one or more processors of an electronic device, cause the electronic device to perform a method of the disclosure.

Any such software may be stored in the form of volatile or non-volatile storage, such as, for example, a storage device like read only memory (ROM), whether erasable or rewritable or not, or in the form of memory, such as, for example, random access memory (RAM), memory chips, device or integrated circuits or on an optically or magnetically readable medium, such as, for example, a compact disk (CD), digital versatile disc (DVD), magnetic disk or magnetic tape or the like. It will be appreciated that the storage devices and storage media are various embodiments of non-transitory machine-readable storage that are suitable for storing a computer program or computer programs comprising instructions that, when executed, implement various embodiments of the disclosure. Accordingly, various embodiments provide a program comprising code for implementing apparatus or a method as claimed in any one of the claims of this specification and a non-transitory machine-readable storage storing such a program.

While the disclosure has been shown and described with reference to various embodiments thereof, it will be understood by those skilled in the art that various changes in form and details may be made therein without departing from the spirit and scope of the disclosure as defined by the appended claims and their equivalents.

No claim element is to be construed under the provisions of 35 U.S.C. § 112, sixth paragraph, unless the element is expressly recited using the phrase “means for” or “means.”

What is claimed is:

1. An electronic device comprising:
a housing including a first housing part and a second housing part, movably coupled to each other;
a driving mechanism configured to cause a movement of the first housing part or a movement the second housing part;
a printed board assembly (PBA) disposed in the first housing part, the PBA including:
a first region which is a laminating region of printed circuit boards, and
a second region which is a non-laminating region;
a battery disposed in the first housing part,
wherein the driving mechanism includes:
an actuator having a rotation axis parallel to a direction of the movement of the first housing part or the second housing part, and
a rack gear disposed parallel to the rotation axis, and
wherein the battery is positioned over the second region among the first region and the second region.

2. The electronic device of claim 1,
wherein the actuator is disposed closer to a first edge portion among the first edge portion of the first housing part parallel to the direction of the movement and a second edge portion of the first housing part, opposite to the first edge portion,
wherein the rack gear is disposed closer to a third edge portion of the second housing part among the third edge portion at least partially coupled to the first edge portion of the first housing part and a fourth edge portion of the second housing part opposite to the third edge portion, and
wherein the battery at least partially occupies a space of the first housing part between the actuator and the second edge portion of the first housing part.

3. The electronic device of claim 1,
wherein the driving mechanism is configured to provide:
a first state in which the second housing part is movable in a first direction among the first direction in which the second housing part moves away from the first housing part and a second direction in which the second housing part approaches the first housing part,
a second state in which the second housing part is movable in the second direction among the first direction and the second direction, and
a plurality of intermediate states between the first state and the second state, and
wherein the rack gear is positioned next to the actuator, in the first state.

4. The electronic device of claim 1, further comprising a flexible display, wherein the flexible display includes:
a planar portion disposed on the first housing part, and
a flexible portion extended from the planar portion, and configured to be at least partially rolled into the second housing part or to be at least partially extracted from an inside of the second housing part, based on a movement of the second housing part.

5. The electronic device of claim 4,
wherein the PBA is adjacent to a fifth edge portion perpendicular to the first edge portion of the first housing part parallel to the direction of the movement and spaced apart from the second housing part, and
wherein an end portion of the second region of the PBA facing an opposite to the fifth edge portion is spaced apart from an end portion of the flexible portion positioned in the second housing part.

6. The electronic device of claim 1, further comprising a bracket including a guide rail to guide translation of the rack gear,
wherein the driving mechanism comprises:
a pinion gear, operatively coupled to the actuator, configured to rotate based on an operation of the actuator, and engaged with the rack gear, and
one or more gear connected to each of the actuator and the pinion gear to transmit driving force from the actuator to the pinion gear,
wherein the guide rail comprises:
a first side wall contacted with a portion of a side of the rack gear, and
a second side wall contacted with a portion of another side of the rack gear opposite to the side of the rack gear, and including an opening region to reduce a gap between the actuator and the rack gear, and
wherein the one or more gears is closer to the second side wall among the first side wall and the second side wall.

7. The electronic device of claim 6, wherein the one or more gears is connected to the pinion gear engaged with the rack gear through the opening region.

8. The electronic device of claim 6, wherein the bracket comprises a third side wall connected to the second side wall and surrounding the one or more gears.

9. The electronic device of claim 8,
wherein the one or more gears comprises:
a first gear including first teeth, and
a second gear including second teeth engaged with the first teeth and configured to cause rotation of the pinion gear based on rotation of the first gear, wherein the driving mechanism comprises:
a first shaft, parallel to the rotation axis, connected to each of the actuator and the first gear, and configured to rotate based on the operation of the actuator, and
a second shaft connected to each of the pinion gear and the second gear, and perpendicular to the first shaft, and
wherein the third side wall comprises:
a first portion extending perpendicular to the second side wall and including a first opening through which the first shaft passes,
a second portion extending perpendicular to an end portion of the first portion and including a second opening through which the second shaft passes, and
a third portion extending perpendicular to an end portion of the second portion to face the first portion.

10. The electronic device of claim 9,
wherein the first side wall includes a third opening through which the second shaft passes, and
wherein the bracket comprises:
a first bearing disposed in the first opening and contacted with the first shaft,
a second bearing disposed in the second opening and contacted with the second shaft, and
a third bearing disposed in the third opening and contacted with the second shaft.

11. The electronic device of claim 1,
wherein the driving mechanism comprises:
a pinion gear, operatively coupled to the actuator, configured to rotate based on an operation of the actuator, and engaged with the rack gear, and
one or more gear connected to each of the actuator and the pinion gear to transmit driving force from the actuator to the pinion gear,
wherein the one or more gears comprises:
a first gear including a first teeth, connected to the actuator, and configured to rotate based on the operation of the actuator, and
a second gear, including a second teeth engaged with the first teeth, connected to the pinion gear, and configured to cause the rotation of the pinion gear based on the rotation of the first gear, and
wherein the actuator has revolutions per minute (RPM) based on a gear ratio according to the first teeth and the second teeth.

12. The electronic device of claim 1,
wherein the driving mechanism comprises:
a pinion gear, operatively coupled to the actuator, configured to rotate based on an operation of the actuator, and engaged with the rack gear, and
one or more gear connected to each of the actuator and the pinion gear to transmit driving force from the actuator to the pinion gear,
wherein the one or more gears is a bevel gear, and
wherein teeth of the rack gear face a front of the electronic device or a rear of the electronic device.

13. The electronic device of claim 1,
wherein the driving mechanism comprises:
a pinion gear, operatively coupled to the actuator, configured to rotate based on an operation of the actuator, and engaged with the rack gear, and
one or more gear connected to each of the actuator and the pinion gear to transmit driving force from the actuator to the pinion gear,
wherein the pinion gear and the one or more gears are a helical gear, and
wherein teeth of the rack gear face a lateral surface of the electronic device.

14. The electronic device of claim 1, further comprising a speaker configured to provide an audio signal and disposed adjacent to the rack gear in the second housing part.

15. The electronic device of claim 1, further comprising a connecting terminal disposed adjacent to the rack gear in the second housing part, and connected to a terminal of an external electronic device.

16. An electronic device comprising:
a housing including:
a first housing part, and
a second housing part movably coupled to the first housing part;
a driving mechanism configured to cause a movement of the second housing part relative to the first housing part, the driving mechanism including:
an actuator disposed in the first housing part to have a rotation axis parallel to a direction of the movement of the second housing part,
a rack gear coupled to the second housing part and extended parallel to the direction,
a pinion gear, operatively coupled to the actuator, configured to rotate based on an operation of the actuator, and engaged with the rack gear, and
one or more gear connected to each of the actuator and the pinion gear to transmit driving force from the actuator to the pinion gear; and
a bracket including a guide rail to guide translation of the rack gear,
wherein the guide rail comprises:
a first side wall contacted with a portion of a side of the rack gear, and
a second side wall contacted with a portion of another side of the rack gear opposite to the side of rack gear, and including an opening region to reduce a gap between the actuator and the rack gear, and
wherein the one or more gears are closer to the second side wall among the first side wall and the second side wall.

17. The electronic device of claim 16,
wherein the bracket comprises a third side wall connected to the second side wall and surrounding the one or more gears,
wherein the one or more gears comprise:
a first gear including first teeth, and
a second gear including second teeth engaged with the first teeth and configured to cause rotation of the pinion gear based on rotation of the first gear, wherein the driving mechanism comprises:
a first shaft, connected to each of the actuator and the first gear and configured to rotate based on the operation of the actuator, and
a second shaft connected to each of the pinion gear and the second gear and perpendicular to the first shaft, and
wherein the third side wall comprises:
a first portion extending perpendicular to the second side wall and including a first opening through which the first shaft passes,
a second portion extending perpendicular to an end portion of the first portion and including a second opening through which the second shaft passes, and
a third portion extending perpendicular to an end portion of the second portion to face the first part.

18. The electronic device of claim 17,
wherein the first side wall includes a third opening through which the second shaft passes, and
wherein the bracket comprises:
a first bearing disposed in the first opening and contacted with the first shaft;
a second bearing disposed in the second opening and contacted with the second shaft; and
a third bearing disposed in the third opening and contacted with the second shaft.

19. The electronic device of claim 16, further comprising:
a printed board assembly (PBA) disposed in the first housing part, the PBA including:
a first region which is a laminating region of printed circuit boards, and
a second region which is a non-laminating region, extended from the first region, and
a battery disposed in the first housing part,
wherein, when the battery is viewed from above, the battery has a length that at least partially overlaps the second region among the first region and the second region.

20. The electronic device of claim 19,
wherein the actuator is disposed closer to a first edge portion among the first edge portion of the first housing part parallel to the direction and a second edge portion of the first housing part opposite to the first edge portion,
wherein the rack gear is disposed closer to a third edge portion of the second housing part among the third edge portion at least partially coupled to the first edge portion of the first housing part and a fourth edge portion of the second housing part opposite to the third edge portion, and
wherein the battery at least partially occupies a space of the first housing part between the actuator and the second edge portion of the first housing part.
